(19) United States
(12) Patent Application Publication
(10) Pub. No.: US 2024/0320393 A1
(43) Pub. Date: Sep. 26, 2024

(54) BUILDING INFORMATION MODELING-BASED SIMULATION OF CONSTRUCTION ROBOTS IN WOOD FRAME ASSEMBLY PROCESS

(71) Applicant: PURDUE RESEARCH FOUNDATION, West Lafayette, IN (US)

(72) Inventors: Jiansong Zhang, West Lafayette, IN (US); Byung Cheol Min, West Lafayette, IN (US); Richard M. Voyles, West Lafayette, IN (US); Oscar Wong Chong, West Lafayette, IN (US)

(21) Appl. No.: 18/615,789

(22) Filed: Mar. 25, 2024

Related U.S. Application Data
(60) Provisional application No. 63/454,489, filed on Mar. 24, 2023.

(51) Int. Cl. G06F 30/20; G06Q 50/08

(52) U.S. Cl. CPC G06F 30/20; G06Q 50/08

(57) ABSTRACT

Methods and systems for performing building information modeling (BIM)-based simulation of robotic construction processes comprise and/or implement receiving a model design input, the model design input including at least one of a BIM design input parameter or a robotic system input parameter, generating a virtual simulation environment based on the model design input, and simulating a construction process by a robotic system in the simulation environment.

### CROSS-REFERENCE TO RELATED APPLICATIONS

This application claims priority to and the benefit of U.S. Provisional Application No. 63/454,489, filed Mar. 24, 2023, the entire contents of which are herein incorporated by reference for all purposes.

### STATEMENT REGARDING FEDERALLY-SPONSORED RESEARCH OR DEVELOPMENT

This invention was made with government support under 1827733 IIP awarded by the National Science Foundation. The government has certain rights in the invention.

### TECHNICAL FIELD

This disclosure relates to the field of automated construction. More particularly, this disclosure relates to systems and methods for virtual design and construction (VDC) to simulate, guide, and instruct construction robots.

### BACKGROUND

Construction, a labor-driven industry, is experiencing a labor shortage amid the accelerated aging of the construction workforce. This labor shortage is negatively affecting the productivity in the construction sector. Moreover, construction is a dangerous industry, with nearly half of the deadliest job tasks in America. Automation in construction, especially with robotics, has the potential to relieve some of the strain imposed by the labor shortage and increase productivity. The presence of robots in construction is becoming prominent. According to some predictions, the number of robots in the construction industry is expected to exceed seven thousand by 2025. Robots excel at performing repetitive tasks with precise motions in controlled environments such as those in offsite construction facilities. In addition, robots save workers from dangerous, repetitive, and labor-intensive tasks, which in turn allows them to focus on more high-level and more meaningful tasks. Therefore, adopting robotic automation by the Architecture, Engineering, and Construction (AEC) industry can bring numerous benefits in terms of productivity, quality, and safety, which is aligned with the goal of restoring and improving the urban infrastructure.

However, the benefits of robotics are not yet fully realized due to its slow adoption rate by the construction sector. Some limiting factors of the slow adoption rate of robotics in construction include high implementation cost, fragmented nature of the industry, incompatibility with current workflows, immaturity of construction robotic technology, among others. One way to help better understand the benefits as well as the challenges of construction robotics is through virtual design and construction (VDC). VDC allows the testing and visualization of processes before the actual construction takes place. For example, 4D simulation and energy simulation can be used for schedule and energy consumption analyses, respectively. In construction robotics, simulation can be used to analyze, test, and visualize construction processes executed by a particular robotic system. One of the challenges in the development and implementation of robotic simulation is the need of expert knowledge from the fields of both robotics and construction, because of the multidisciplinary involvement from various stakeholders, including general contractors, robot developers, and researchers. Furthermore, robots should be provided with accurate and explicit information to reliably perform the designated tasks. For instance, frames of reference and dimensions of objects are information that determine how robots interact with the objects and their environment. These challenges demand thorough planning and coordination, and absolute accuracy in the design information is required for successful analyses.

### SUMMARY

These and other problems may be overcome by systems, methods, and devices having configurations as set forth herein. Thus, the present disclosure provides systems and methods to perform analysis on building information modeling (BIM) design models to more fully automate the construction design, robot instruction, and construction processes.

According to one aspect of the present disclosure, a BIM simulation system is provided. The system comprises a processor and a memory storing instructions that, when executed by the processor, cause the system to perform operations comprising receiving a model design input, the model design input including at least one of a BIM design input parameter or a robotic system input parameter, generating a virtual simulation environment based on the model design input, and simulating a construction process by a robotic system in the simulation environment.

According to another aspect of the present disclosure, a method of simulating a BIM environment is provided. The method comprises receiving a model design input, the model design input including at least one of a BIM design input parameter or a robotic system input parameter, generating a virtual simulation environment based on the model design input, and simulating a construction process by a robotic system in the simulation environment.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements. It should be understood that the drawings are not to scale unless otherwise indicated.

FIG. 1 illustrates an example methodology in accordance with various aspects of the present disclosure.

FIG. 2A illustrates an example of a target location determination operation in accordance with various aspects of the present disclosure.

FIG. 2B illustrates an example of a target location determination operation in accordance with various aspects of the present disclosure.

FIG. 3 illustrates an example definition of nailing positions in accordance with various aspects of the present disclosure.

FIG. 4 illustrates example framing operations in accordance with various aspects of the present disclosure.

FIG. 5 illustrates an example flowchart of framing subroutines in accordance with various aspects of the present disclosure.

FIG. 6 illustrates an example frame in accordance with various aspects of the present disclosure.

FIG. 7 illustrates an example frame in accordance with various aspects of the present disclosure.

FIG. 8 illustrates an example structure in accordance with various aspects of the present disclosure.

FIG. 9 illustrates an example wall layout in accordance with various aspects of the present disclosure.

FIG. 10 illustrates an example wall layout in accordance with various aspects of the present disclosure.

FIG. 11A illustrates an example robot model in accordance with various aspects of the present disclosure.

FIG. 11B illustrates an example robot model in accordance with various aspects of the present disclosure.

FIG. 12A illustrates an example end effector in accordance with various aspects of the present disclosure.

FIG. 12B illustrates an example end effector in accordance with various aspects of the present disclosure.

FIG. 13 illustrates an example conveyor model in accordance with various aspects of the present disclosure.

FIG. 14 illustrates an example spatial layout of simulation components in accordance with various aspects of the present disclosure.

FIG. 15 illustrates an example initial element distribution in accordance with various aspects of the present disclosure.

FIG. 16A illustrates an example framing operation in accordance with various aspects of the present disclosure.

FIG. 16B illustrates an example nailing operation in accordance with various aspects of the present disclosure.

FIG. 17 illustrates an example test model integration in accordance with various aspects of the present disclosure.

FIG. 18 illustrates an example test model integration in accordance with various aspects of the present disclosure.

FIG. 19 illustrates an example test model integration in accordance with various aspects of the present disclosure.

FIG. 20 illustrates an example test model integration in accordance with various aspects of the present disclosure.

FIG. 21 illustrates an example test model integration in accordance with various aspects of the present disclosure.

FIG. 22A illustrates an example framing operation in accordance with various aspects of the present disclosure.

FIG. 22B illustrates an example nailing operation in accordance with various aspects of the present disclosure.

FIG. 23A illustrates an example framing operation in accordance with various aspects of the present disclosure.

FIG. 23B illustrates an example nailing operation in accordance with various aspects of the present disclosure.

FIG. 24A illustrates an example framing operation in accordance with various aspects of the present disclosure.

FIG. 24B illustrates an example nailing operation in accordance with various aspects of the present disclosure.

FIG. 24C illustrates an example framing operation in accordance with various aspects of the present disclosure.

FIG. 24D illustrates an example framing operation in accordance with various aspects of the present disclosure.

FIG. 25 illustrates example connection points in accordance with various aspects of the present disclosure.

FIG. 26 illustrates example connection points in accordance with various aspects of the present disclosure.

FIG. 27 illustrates an example collision in accordance with various aspects of the present disclosure.

FIG. 28 illustrates an example adjusted tool table in accordance with various aspects of the present disclosure.

FIG. 29 illustrates an example plot of time vs. number of elements according to a comparative example.

FIG. 30 illustrates an example time comparison in accordance with various aspects of the present disclosure.

FIG. 31 illustrates an example system in accordance with various aspects of the present disclosure.

FIG. 32 illustrates an example method in accordance with various aspects of the present disclosure.

### DETAILED DESCRIPTION

The detailed description set forth below in connection with the appended drawings is intended as a description of various configurations and is not intended to represent the only configurations in which the subject matter described herein may be practiced. The detailed description includes specific details to provide a thorough understanding of various embodiments of the present disclosure. However, it will be apparent to those skilled in the art that the various features, concepts, and embodiments described herein may be implemented and practiced without these specific details.

As used herein, unless otherwise limited or defined, discussion of particular directions is provided by example only, with regard to particular embodiments or relevant illustrations. For example, discussion of “top,” “front,” or “back” features are generally intended as a description only of the orientation of such features relative to a reference frame of a particular example or illustration. Correspondingly, for example, a “top” feature may sometimes be disposed below a “bottom” feature (and so on), in some arrangements or embodiments. Further, references to particular rotational or other movements (e.g., counterclockwise rotation) is generally intended as a description only of movement relative to a reference frame of a particular example of illustration. Moreover, discussion of “horizontal” or “vertical” features may in some implementations be relative to the earth's surface; however, in other implementations a particular component may be installed in a different orientation such that a “horizontal” feature is not necessarily parallel to the earth's surface.

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as, e.g., “either,” “one of,” “only one of,” or “exactly one of.” Further, a list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of each of A, B, and C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C. In general, the term “or” as used herein only indicates exclusive alternatives (e.g., “one or the other but not both”) when preceded by terms of exclusivity, such as, e.g., “either,” “one of,” “only one of,” or “exactly one of.”

The present disclosure may be implemented on or with the use of computing devices including control units, processors, and/or memory elements in some examples. As used herein, a “control unit” may be any computing device configured to send and/or receive information (e.g., including instructions) to/from various systems and/or devices. A control unit may comprise processing circuitry configured to execute operating routine(s) stored in a memory. The control unit may comprise, for example, a processor, microcontroller, application-specific integrated circuit (ASIC), field-programmable gate array (FPGA), and the like, any other digital and/or analog components, as well as combinations of the foregoing, and may further comprise inputs and outputs for processing control instructions, control signals, drive signals, power signals, sensor signals, and the like. All such computing devices and environments are intended to fall within the meaning of the term “controller,” “control unit,” “processor,” or “processing circuitry” as used herein unless a different meaning is explicitly provided or otherwise clear from the context. The term “control unit” is not limited to a single device with a single processor, but may encompass multiple devices (e.g., computers) linked in a system, devices with multiple processors, special purpose devices, devices with various peripherals and input and output devices, software acting as a computer or server, and combinations of the above. In some implementations, the control unit may be configured to implement cloud processing, for example by invoking a remote processor.

Moreover, as used herein, the term “processor” may include one or more individual electronic processors, each of which may include one or more processing cores, and/or one or more programmable hardware elements. The processor may be or include any type of electronic processing device, including but not limited to central processing units (CPUs), graphics processing units (GPUs), ASICs, FPGAs, microcontrollers, digital signal processors (DSPs), or other devices capable of executing software instructions. When a device is referred to as “including a processor,” one or all of the individual electronic processors may be external to the device (e.g., to implement cloud or distributed computing). In implementations where a device has multiple processors and/or multiple processing cores, individual operations described herein may be performed by any one or more of the microprocessors or processing cores, in series or parallel, in any combination.

As used herein, the term “memory” may be any storage medium, including a non-volatile medium, e.g., a magnetic media or hard disk, optical storage, or flash memory; a volatile medium, such as system memory, e.g., random access memory (RAM) such as dynamic RAM (DRAM), synchronous dynamic RAM (SDRAM), static RAM (SRAM), extended data out (EDO) DRAM, extreme data rate dynamic (XDR) RAM, double data rate (DDR) SDRAM, etc.; on-chip memory; and/or an installation medium where appropriate, such as software media, e.g., a CD-ROM, or floppy disks, on which programs may be stored and/or data communications may be buffered. The term “memory” may also include other types of memory or combinations thereof. For the avoidance of doubt, cloud storage is contemplated in the definition of memory.

BIM may be used as a modality for the design, planning, construction, and operation of a built environment. BIM is a modeling technology and associated set of processes to produce, communicate, and analyze building models. BIM may be implemented in the Architecture, Engineering, and Construction (AEC) industry to achieve collaboration among stakeholders in the modeling and analysis processes at different life cycle phases of a facility. In some comparative examples, BIM may be used in different analyses of a construction project such as cost estimation, schedule simulation, and building energy consumption, among others. However, comparative example construction workflows are incompatible with automation technologies (e.g., robotics), comparative BIM authoring tools do not have the capabilities to perform robotic automation planning, and comparative methods for planning and simulating construction robots are lacking. The limited interoperability between design and construction tools in the comparative examples requires manual transfer and integration of data between design and construction phases, which is time consuming, tedious, and prone to errors. This limitation contributes to the substantial cost ($15.8 billion per year) that the AEC industry incurs due to the difficulty of interoperability.

The present disclosure provides systems and methods to address the interoperability gap, for example via automated extraction and analysis of BIM design parameters to generate a robotic fabrication plan for an offsite construction automation system. The methodology leverages BIM design models as input data and integrates a simulation-based approach to emulate the robotic automation of wood frame assembly. The methodology involves developing a set of algorithms for robotic systems to automatically perform the framing and fastening operations based on the extracted and analyzed input data from BIM.

The BIM design models described herein are reliable digital representations of building designs and a shared knowledge resource for information about a facility forming a reliable basis for decisions during its life cycle. As such, they provide a 3D model with its physical and functional information that can support the analysis of construction processes such as those in the assembly of wood frames. The approaches described herein extract data from the BIM design models of a candidate structure as input for a simulation to assess the feasibility of automated construction of the candidate structure by a particular automated construction system. This direct linkage of design models to fabrication reduces the likelihood of errors in the transition from representation to actualization and increases the speed and accuracy of the bidding process. BIM-based data include building element type (e.g., beam or column), element dimensions (e.g., length, width, height), and element location (e.g., cartesian points with respect to the global coordinates of the BIM design model). The data are extracted and derived using a logic-based method (i.e., logic representation and reasoning) to analyze building design information. In the logic-based method, the building design information, in the form of BIM design model, is converted into logic facts. In addition to the logic facts, a set of logic rules, which can be classified as information classification, information inference, or information filtering rules, are required for automated reasoning. Once the logic facts and logic rules are readily present, the logic reasoning is executed in an automated manner, resulting in the target information for construction robots. Finally, according to the desired performance, the logic facts and/or logic rules can be refined and/or extended. In some implementations of the present disclosure, the open standard Industrial Foundation Classes (IFC) was selected because of its openness and transparency, which may provide improved interoperability in the AEC domain due to inherent limitations that may be present when using proprietary data exchange formats.

In some examples of the present disclosure, a robotic system analysis approach is employed rather than focusing only on individual components (e.g., a particular robot, or end effector, or fixture). A robot by itself provides the illustration of generalized motion, but only when it is complemented with other components such as sensors, end effectors, fixtures, software, and other domain-specific components, can the holistic interaction of the different components within the system be fully evaluated with regard to opportunities for automation. Therefore, the robotic system analysis approach is a comprehensive solution to the automation of the construction process. As a result, it is expected to achieve higher accuracy than the analysis of its individual components.

Some examples described herein are based on computer simulation, which can be used to design, understand, predict, evaluate and verify the states of a system. A simulation-based approach allows the generation and evaluation of different configurations and scenarios of a target robotic construction system and allows for the comparison of different robotic construction systems for bid analysis. By allowing the testing of different alternatives, each simulation scenario provides knowledge about the dynamic behavior of a system and therefore the range of structures it can fabricate. Moreover, the simulation-based approach is a rapid and cost-effective alternative to the testing of the actual physical robotic systems, used during the preconstruction phase and can lead to more accurate bidding and more efficient construction automation. For example, potential issues can be identified during the simulation of the construction operations and subsequently addressed, either in the configuration of the robotic system or in the design of the structure, before the implementation of the actual physical system. The present disclosure sets forth the integration of BIM data to generate information for the emulation of spatiotemporal behavior of a robotic system for wood construction.

### Comparative Examples

Comparative examples of efforts have been undertaken in the area of robotic research for construction in general. The beginning of these efforts focused on single-purpose robots. In some comparative examples, the focus was on concrete and steel buildings with applications such as finishing of concrete floor slabs, positioning of steel members in steel erection, and fireproofing of structural steel members. Other comparative examples can be found in the implementation of robotics for wood construction; for example, the implementation of robotics in full scale architectural structures through digital fabrication.

One comparative example is a robotic system called Robotic Timber Construction (RTC), which employs a design-to-fabrication digital workflow for the assembly of non-standard timber structures. RTC consists of three main components: 1) Design Processes, 2) Material and Constructive Systems, and 3) Integrated Robotic Fabrication. In the Design Processes, RTC used an assembly driven approach that adapts to different functional requirements (e.g., structural integrity and construction tolerances in real time), considering criteria such as material and construction. This component was developed in Python and embedded in Rhinoceros-3D (CAD tool). In Material and Constructive Systems, a connection typology (at non-orthogonal angles) and gluing technique were used for the self-supported elements instead of the orthogonal placement of the elements and connections, respectively. Finally, in the Integrated Robotic Fabrication component, the prefabrication and assembly steps were integrated in a single workflow: (1) grip, (2) cut at the ends, (3) perforate, and (4) move to final position. This allowed a continuous and automated workflow from design to construction. The robotic system of the RTC consisted of a custom six-axis overhead gantry robot having a workplace of 48×6.1×1.9 m (capable of handling timber components between 0.50 m to 10 m in length) and was tested in the construction of the Sequential Roof.

Another comparative example is a robotic system for the prefabrication of functional volumetric timber components on a 1:1 scale. This method provided continuity in the digital process at the assembly stage, which minimizes information loss and precision issues. The robotic system consisted of many integrated components including scanning devices, two industrial robots with pneumatic grippers (ABB IRB 4600-40/2.55) and mounted on a 5 m linear axis carriage, a CNC saw (with servo motors for three controllable axes), and a worktable (6 m×2.2 m) with aluminum rails for fixing wood structures. The software used include Rhino (in C # script), Karamba, and ABB Robotstudio (in Python script) for the fabrication geometry, structural calculation, and robot controller, respectively. In terms of implementation, the robotic cell was capable of creating spatial, structural, functional, and customized timber frame volumetric modules from unprocessed raw timber material as well as timber beams and panels with variable dimensions.

Yet another comparative example is an automated method in the production of a full-scale timber structure using robots, to minimize material waste and cost. The tested timber structure consisted of 18 framing elements placed horizontally, forming a uniquely shaped structural system. The ABB IRB2600-20/1.65 industrial robot was used for the cutting and assembly of timber elements. Another presented a process to produce a spatial timber structure using the KR 150 L110-2 KUKA robot for the robotic fabrication and assembly of the optimized space-frame structure. These comparative implementations were on non-conventional projects (i.e., free-form structures and other special topology configurations of wood construction), which are usually one-off projects and are far less common compared to other practices such as frame construction. In addition, the representation of the building models in their workflows/systems was based on proprietary CAD platforms (e.g., Rhinoceros). The dependency on multiple proprietary CAD/BIM platforms instead of open BIM (e.g., IFC), limits the feasibility of a seamless workflow in the implementation of automation in offsite construction and is a differentiator of the systems and methods in accordance with the present disclosure.

BIM plays a role in construction workflows. BIM data serves as a single and centralized source of information for all building related processes. As such, it provides data for the different analyses required during the life cycle of a construction project. In the context of offsite construction, BIM may be used for design, manufacturability verification, assembly optimization, and structural health monitoring purposes. For instance, in a comparative example a VBA-based CAD system takes information from BIM to automate the design and drafting processes of wood panels. In another comparative example, a system to check the manufacturability of wood frame assemblies was implemented. Other comparative examples include a system to increase the efficiency and reduce the waste in the assembly process of offsite construction, and a BIM-based data management system applied for structural health monitoring of modular buildings. However, even in these comparative examples, the integration of the BIM-based workflow with robotic technology is still lacking.

### Simulation-Based Methodology

Uncertainties and risks are common in construction, and they often lead to delays and/or economic losses in construction projects when they are overlooked or have not been properly taken into consideration in advance. Virtual design and construction (VDC) provide a way to identify and test potential solutions to minimize risks in construction projects. VDC is the process of testing construction operations in a virtual environment before the actual construction process takes place. VDC can be performed through simulations. In a broad sense, simulation is an approximation of a mathematical model to analyze a system. Simulations can be used to analyze, visualize, and explore construction operations in a safe and virtual environment. Examples of basic simulation methods include discrete-event simulation, agent-based modeling, and system dynamics.

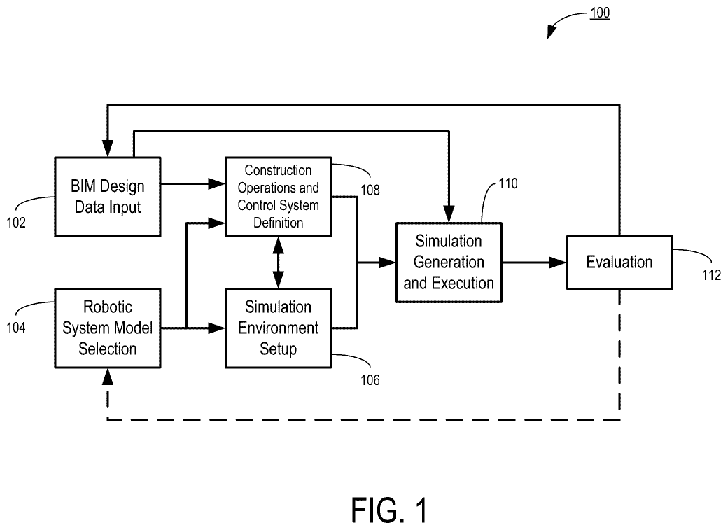

The systems and methods herein aim to generate simulations of robotic systems based on building design information, to support the analysis of offsite construction automation. The building designs, in the form of IFC-based BIM instance models, are used as input to the simulation. The simulated construction process involves the assembly of wood frames by a robotic system. The assembly process comprises of a set of framing and connection operations on wood elements. The simulation methodology 100 is divided into six phases, as illustrated in FIG. 1: 1) BIM Design Data Input 102, 2) Robotic System Model Selection 104, 3) Simulation Environment Setup 106, 4) Construction Operations and Control System Definition 108, 5) Simulation Generation and Execution 110, and 6) Evaluation 112.

In phase 102, the initial input for the methodology consists of building design data derived from BIM instance models. The IFC-based BIM data includes the order of the building elements (e.g., bottom plate→studs→top plate), dimensions and weights of the building elements, and location (position and orientation of the elements relative to the BIM design model coordinate system) that are extracted and derived from IFC models. The extraction and inference make use of logic reasoning, which comprise of logic facts (converted from IFC models) and logic rules (extraction, inference, and filtering rules) to obtain the input information for the simulation. The BIM data input used for the simulation environment and for the robot controller are shown in Table 1 and Table 2, respectively.

TABLE 1
BIM input data for the simulation environment

| Input Data | Description |
|---|---|
| Density of element | The density of the elements was assigned to the element during the |
| | matching of the elements from BIM input to the simulation world. |
| Sequence of construction | The sequence of the construction was determined using a soft |
| | sequencing requirement (i.e., any feasible sequence without |
| | optimization consideration). The elements are instantiated in the |
| | simulation environment according to the determined order. |
| Dimension | The dimension was mapped to the simulation objects. |
| Position and orientation | This element is the position in the simulation environment and the |
| | orientation of the cross section. |

TABLE 2
BIM input data for the robot controller.

| Input Data | Description |
|---|---|
| Name | The name of the element provides a unique identifier and the type |
| | of elements (e.g., beam23, column45). |
| Local placement | The local placement location is the centroid of one of the extreme |
| | end's cross-section of the element relative to the global coordinate |
| | system of the BIM design model. |
| Main axis | The main axis refers to the orientation of the longitudinal axis of the |
| | element relative to the local coordinate system of the element's |
| | cross section. For a regular element, it corresponds to the extrusion |
| | of the element when using solid sweeping 3D representation. In |
| | IFC, it is the direction of the z-axis in the coordinate system of the |
| | element's cross section. |
| Dimension | Dimensions include the width, depth, and height of a stud element. |

Phase 104 is the selection of the robotic system. This phase comprises selecting the components of the robotic system to support the assembly process of wood frames. In an example, the components of a robotic system refer mainly to the physical components of a robotic cell such as robot, end-effectors, fixtures, material handling devices, and sensors. A brief description for each component is provided in Table 3. The selection of the components is based on its specifications and functions in the assembly process and can be divided into two steps: 1) define the specifications for the components of the robotic system, and 2) select the components of the robotic system.

TABLE 3
Description of robotic system components.

| Robotic system | | |
|---|---|---|
| component | Definition | Description |
| Robot | According to the ISO (International | Performs the framing and nailing |
| | Organization for Standardization) | operations in the frame assembly. |
| | 8373, a robot is an actuated | For example, industrial arms. |
| | mechanism programmable in two or | |
| | more axes with a degree of autonomy, | |
| | moving within its environment, to | |
| | perform intended tasks. | |
| End-effector | A tool to enable robots to interact with | Tools attached at the end of the |
| | environments. | robot's arm for gripping, fastening |
| | | elements, etc. Examples include |
| | | grippers, nailing gun, or other |
| | | tools. |
| Material handling | A device used to move materials | Transport and feed materials to the |
| device | between specific points on a fixed | robot. Examples include |
| | path. | conveyor, which can be single or a |
| | | system of conveyors. |
| Fixture | A fixture is any tools that support the | Examples include tables, floors, |
| | assembly process. | and other tools. |
| Sensor | A device that receives a stimulus and | Allows the perception of the |
| | responds with an electrical signal. | environment and the measurement |
| | | of parameters of the robotic |
| | | system (e.g., joint angles). |
| | | Examples include displacement, |
| | | rotation, and touch sensors. |

The first step of phase 104 is to narrow down the number of alternatives for the selection of the robotic system components based on the constraints, specifications, or performance criteria for each of the components in the framing and nailing processes. Examples of specifications for a robotic system component include the load capacity and the reach of the robot which are indicative of how heavy and how far a robot can carry and reach, respectively. Another example could be the speed of the conveyors. Once the specifications are defined, the selection of the specific components of a robotic system can be performed. In this step, it is assumed that sufficiently flexible automated fixturing is provided to immobilize the wood frame components wherever they are placed by the robot.

The second step of phase 104, after the definition of the specifications and functions for each component of the robotic system, is to select the specific components. The selection of the components can be from existing commercially available components or conceptualized components (e.g., new robotic design) that meets the automation requirements/specifications of the assembly process.

Following the selection of the robotic system components, phase 106 is the setup for the simulation. This phase consists of four steps: 1) create the models of the construction materials, 2) create/import the models of the robotic system components, 3) aggregate the models of the robotic system components into assemblies, and 4) define the layout of the robotic system.

In the first step, the construction materials of interest for wood construction are the 2×4 and 2×6 studs because they are used as vertical framing members in wall structures. In the simulation environment, the respective 3D models of the wood studs for the simulation of the assembly process are created. The models of the studs serve as templates in the mapping process (in subsequent steps) from the BIM data to the stud models of the simulation. During the mapping process, the lengths and density of the stud models are adjusted accordingly based on the BIM data input.

The next step creates or imports the 3D models of the selected robotic system components in the simulation. The 3D models can be created using the built-in modeling tool of the robotic simulator or in any 3D modeling software and then imported to the simulation environment. Following that, parameters of the created/imported models such as bounding box, physics, anchor points and movement ranges of the joints may be verified and adjusted if needed for its correct function in the simulation.

In the third step, simple 3D models can be aggregated into a single model called assembly to represent or form more complex models. For example, basic 3D objects can be aggregated into assembly to represent the different links (i.e., components) of a robot, while the models of the links (i.e., assemblies) can be further aggregated into another assembly to form a multi-degree-of-freedom robot model. Assemblies facilitate the reuse and instantiation of complex objects in the simulation environment. In addition, an assembly provides the flexibility to customize parameters in the simulation environment. Some common modifiable parameters include translation, orientation, and size of the 3D model assembly.

The spatial layout of the components within a robotic system affects the workflow of the system. For example, the workspace of the assembly area needs to be defined to avoid potential collisions with other components (e.g., feeding devices). Therefore, the fourth step considers the different layout configurations of each individual component in the planning of the assembly process. Some considerations in the definition of the spatial layout include the relative location and orientation of each component of the robotic system within the workspace of the simulation world.

Returning to FIG. 1, in phase 108 the behavior of the robotic system is defined, coded, and integrated in the control system based on the construction operations (i.e., assembly process). The control system defines the behavior of the robotic system to perform the assembly operations, based on the information provided from the BIM data input. The creation of the control system involves six steps: 1) determine the framing target locations for the framing operation, 2) determine the nailing target locations for the nailing operation, 3) define the placement orientation of the frame with respect to the robot, 4) define and create the subroutines for the robot, 5) code the control system and BIM data in the robot controller, and 6) define the behavior for the robotic system components.

In the first step, the framing target locations refer to the center of mass of the elements relative to the origin of the robot's base. In other words, a framing target location is the cartesian point measured from the robot's coordinate system to the center of mass of the element in the final assembled (constructed) state of the frame. The framing target locations are determined based on the data from the BIM design models, which are provided as BIM data input. This data includes locations of local placement, dimensions, and orientations of the main axis for each of the elements as defined in the BIM data input.

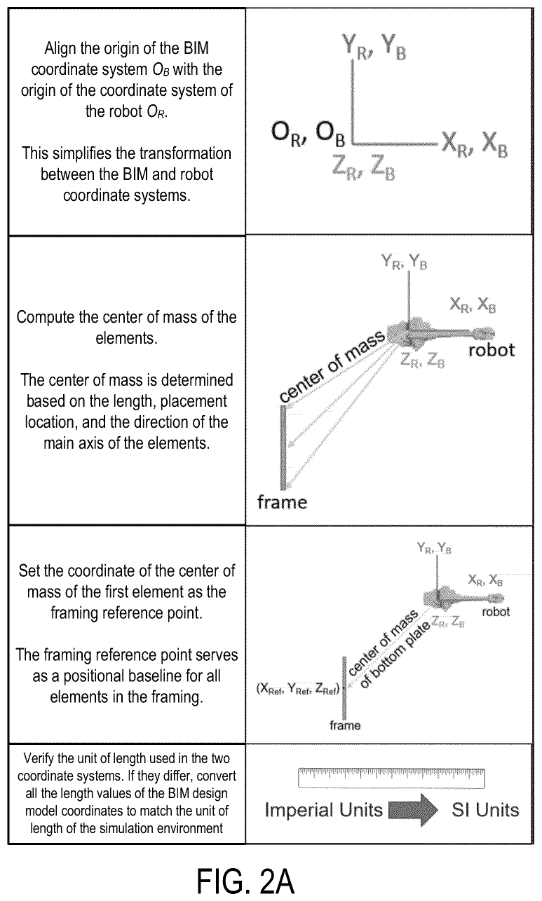

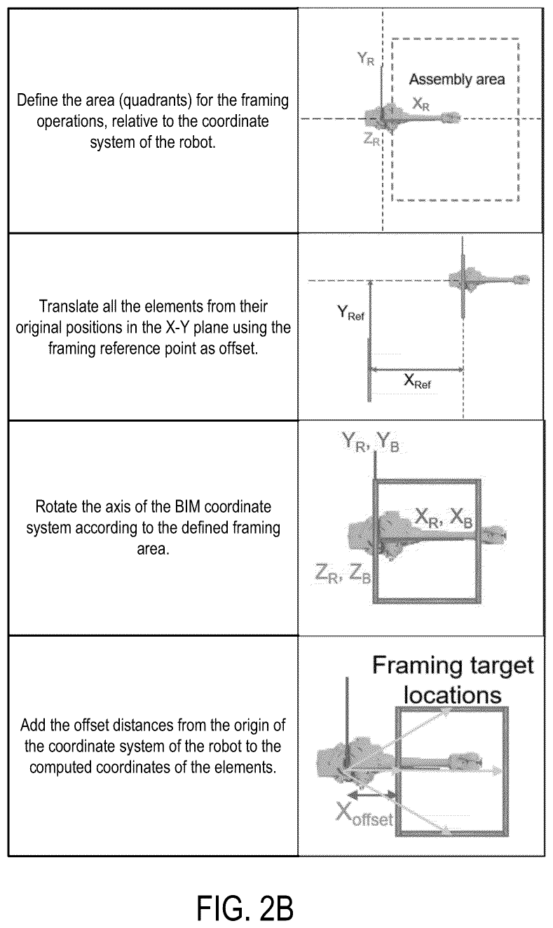

Following that, a series of coordinate transformations are performed. The coordinate transformations for the framing operation are divided into eight sub-steps and involve three Cartesian coordinate systems: 1) global coordinate system of the BIM design model, 2) local coordinate system of the robot, and 3) global coordinate system of the simulation world. To reduce the complexity of the transformation process, the origin of the local coordinate system of the robot is set to overlap with the origin of the global coordinate system of the simulation world. The sub-steps for the coordinate transformations are illustrated in FIGS. 2A and 2B.

In the seventh sub-step (see FIG. 2B), the number of rotations depends on the orientation of the wall in the BIM design model relative to the robot. For instance, if the original position of a wall in the BIM design model is perpendicular to the robot, two rotations (Z₉₀ and Y₉₀) are needed. In another case, if the wall is parallel to the robot, only one rotation of Y₉₀ axis is sufficient. The perpendicularity of a building component, in this case a wall, depends on the wall positioning and orientation of the BIM design model. The Y or the X dimensions in the BIM design model coordinate system become the Y of the robot's coordinate system based on if the wall is parallel or perpendicular to the robot. The Z dimensions in the BIM design model coordinate system becomes the X in the simulation coordinate system.

In the second step of phase 108, the target locations for the nailing operation are defined. The nailing target locations are the locations where the robot performs the nailing operations to connect the elements in the frame, relative to the coordinate system of the robot. The nailing target locations are determined based on the framing target locations according to Eq. (1), Eq. (2), and Eq. (3) based on the nailing schedule for studs and plates (top and bottom) connections.

$${N}_{x}^{ij} = {x}_{t}^{{plate}_{i}} - \frac{{thickness}^{{plate}_{i}}}{2} \qquad ( 1 )$$

$${N}_{y}^{ij} = {y}_{t}^{{stud}_{j}} \qquad ( 2 )$$

$${N}_{z}^{ij} = \{ \begin{matrix}{z}_{t}^{{plate}_{i}} - \frac{{width}^{{plate}_{i}}}{6} \\ {z}_{t}^{{plate}_{i}} + \frac{{width}^{{plate}_{i}}}{6}\end{matrix} \qquad ( 3 )$$

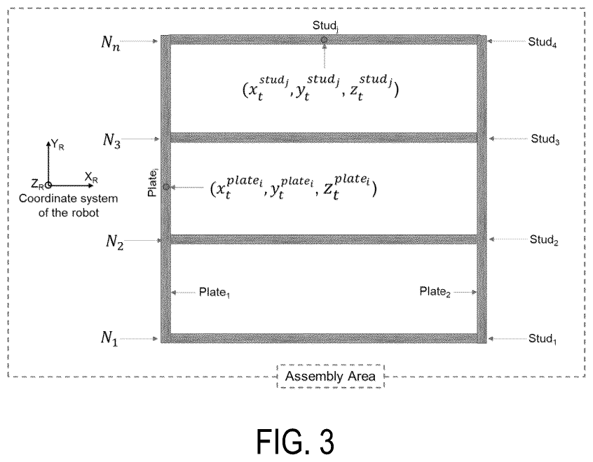

In Eqs. (1)-(3), Nₓ^{ij} is the x component of the nailing target location between plate i and stud j, N_{y}^{ij} is the y component of the nailing target location between plate i and stud j, N_{z}^{ij} is the z component of the nailing target location between plate i and stud j, xₜ^{plate}^{ᵢ} is the x component of the center of mass location of plate i, xₜ^{plate}^{ᵢ} is the z component of the center of mass location of plate i, yₜ^{stud}^{ⱼ} is the y component of the center of mass location of stud j, width^{plate}^{ᵢ} is the width of plate i, and thickness^{plate}^{ᵢ} is the thickness of plate i. The two values for N_{z} in Eq. (3) correspond to the two nailing locations in the z-axis. A representation of the nailing target locations in a frame is shown in FIG. 3.

In the third step of phase 108, the placement orientation for the frame is defined. The orientation of the frame determines the orientation of its elements. The orientation can be perpendicular, parallel, or at an angle with respect to the y-axis of the robot. A parallel orientation means that the length (left-right direction of the frame) of the frame is parallel to the y-axis of the robot (left-right side of the robot), while a perpendicular orientation means that the height (bottom-top direction) is parallel to the y-axis of the robot. Once the orientation of the frame is defined, the longitudinal axis for each element is determined, and this information is included in the controller in order to provide the direction for the placement of the elements in the framing and nailing operations.

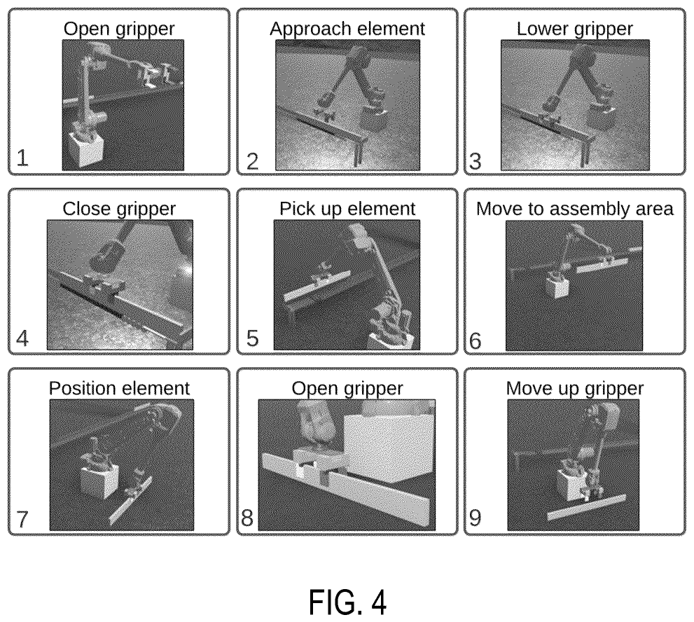

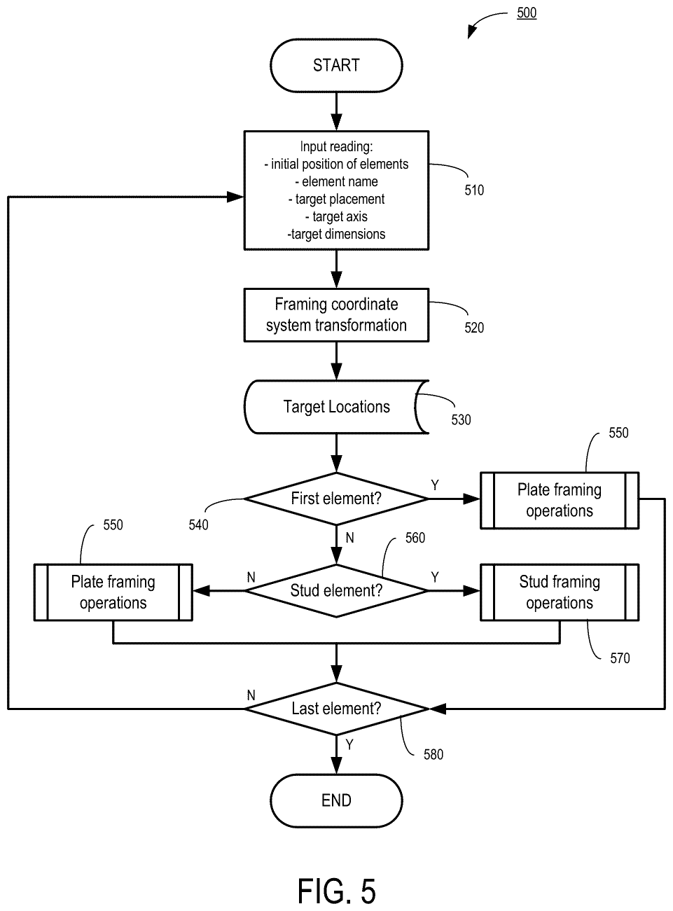

In the fourth step, the subroutines for the framing and nailing operations are defined and created to enable the robotic system to perform the operations automatically. The framing and nailing subroutines comprise a list of operations such as pick, move, and open/close grippers. The subroutines take the location of the elements from the feeding device (conveyor tray), the type of element, and the framing and nailing target locations as input. Based on the type of element (i.e., plate, stud) and its order (i.e., construction sequence), the robot performs the corresponding subroutine (i.e., framing, nailing). Each complete cycle of the subroutine corresponds to the framing of an element. Examples of framing operations are shown in FIG. 4. A flowchart for the framing subroutine 500 is shown in FIG. 5.

The subroutine 500 begins with an operation 510 of reading an input, the input including at least one of an initial position of the elements, a set of element names, a target placement location, a target axis, or target dimensions. Next, at operation 520, a framing coordinate system transformation is performed. At operation 530, a set of target locations is stored in a memory element (e.g., in a local memory and/or in a database). Operations are then iteratively performed on each of the elements. At operation 540, it is determined whether an element is the first element. If the element is the first element, at operation 550 plate framing operations are performed. If the element is not the first element, the subroutine 500 moves to operation 560, where it is determined whether the element is a stud element. If the element is not a stud element, the subroutine 500 moves to operation 550 to perform plate framing operations. If the element is a stud element, the subroutine 500 moves to operation 570 to perform study framing operations. In either case, after the plate or stud framing operations are performed, at operation 580 it is determined whether the element was the last element. If the element was not the last element, the subroutine 500 returns to operation 510 for one or more subsequent iterations. If the element was the last element, the subroutine 500 terminates. In FIG. 5, the plate framing and stud framing operations 550 and 570 are predefined operations.

Controllers contain the instructions (e.g., subroutines) for the robotic system to perform the assembly process. In the fifth step of phase 108, the control of the robot is determined using inverse kinematics (IK), which takes the cartesian position of the end-effector to compute the joint angle of each link joint. The IK function along with the framing and nailing subroutines can be integrated in the controller or used as a support module to the controller. In one example of the present disclosure, the latter case is used to increase the modularity of the algorithm. In addition, the BIM data are included in the controller and are used to determine the target locations for the framing and nailing operations, which in turn are used in the framing and nailing subroutines for the execution of the assembly process. The BIM data are included in the controller as input, which include the name, local placement, main axis, and dimension of the elements (as specified above with regard to the first step of phase 108).

In the sixth step, the behavior of the robot is defined in the framing and nailing subroutines. Now, the behavior for the other components of the robotic system is defined for the assembly process. For example, the movement of materials by the handling devices (i.e., conveyors) is set to move at a constant speed instead of a predefined distance. As another example, a touch sensor with an emitter is created at the end of the second conveyor to signal the robot when an element is ready for pick up, while stopping the movement of the conveyors until the current element is picked up by the robot in the framing process. The defined behaviors are then coded and integrated into their respective component controllers when applicable. Some behaviors may be integrated into the robot's controller (e.g., the open and close functions of the parallel gripper).

Returning to FIG. 1, in phase 110 the simulation file is generated, which may include the robotic system components and BIM data from the previous phases 102-108. The generation process and execution of the simulation comprises four steps: 1) map the BIM building elements to the construction materials from the simulation, 2) define the initial position and orientation of the construction materials in the simulation environment, 3) generate the simulation file, and 4) execute the simulation file.

In the first step of phase 110, the building elements (e.g., columns and beams) from BIM are automatically mapped to the created construction materials (i.e., studs) in the simulation environment. Information such as dimensions, weight (density), quantities for each stud are mapped to the studs of the simulation.

In the second step, the elements are generated in the simulation environment according to the sequence of bottom plate→studs→top plate in the first conveyor. Each element is positioned parallel to each other and separated with a constant spacing to avoid misalignment and prevent collision between elements, respectively, during the transfer to the next conveyor. The longitudinal axis of the elements is aligned with the next element on the conveyor in a straight path while the element is standing on one of its narrower side surfaces. This facilitates the grasping operations by the robot and avoids the need of rotating the elements during the assembly operations.

In the third step of phase 110, the simulation file that contains the information from the previous phases 102-108 such as simulation assets (i.e., 3D models of the robotic system components, building elements, controllers, and properties) is dynamically generated and loaded. The generation and loading processes are conducted through programming. The model directory structure of the robotic simulator, which describes the file hierarchy (how files are organized) of a project in Webots, is to be followed in order for these processes to work.

Once the simulation file that contains the assemblies and the embedded controllers for the robotic system is generated, the simulation is ready to be executed at the fourth step of phase 110. The simulation automatically starts when the simulation file is executed. During the simulation, the robotic system performs the programmed assembly subroutines.

Phase 112 of the methodology 100 evaluates the performance of the simulation. The evaluation process can be divided into three categories: 1) BIM-simulator integration, 2) assembly process simulation, and 3) collision detection. In the first category, the information generated (e.g., building materials) in the simulation environment are compared against the building elements in the BIM design model to verify the accuracy of the mapping and generation processes. Second, the simulation of the assembly process is evaluated to determine the performance of the construction algorithms (e.g., framing and nailing subroutines), which are based on BIM data. This evaluation identifies components of the robotic system that did not perform as intended due to their insufficiency and/or inaccuracy of the BIM data. The visualization of the simulation allows users to inspect specific operations performed by the robotic system. In addition, spatial and temporal information are used to identify any unexpected behavior of the robotic system components during the construction operations. The third category is the collision detection between the components of the robotic system or with any objects within its workspace, which can cause failure of the assembly operations.

The output of this evaluation determines the adequacy of the BIM data, the generated construction operations, and the selected robotic system components for the assembly process. The evaluation phase 112 forms a feedback loop to the reselection/modification of any components of the robotic system (if needed) and/or the BIM data to improve the current assembly process.

### Example Implementation

In one particular example, the method 100 was implemented using Webots, an open-source robotic simulator developed by Cyberbotics Ltd®. Webots provides a prototyping environment for modeling, programming, and simulation of robots. Regarding the IK, the solver IKPy (implemented as a Python library) was used to handle the computation of the joint parameters according to the cartesian coordinates of the end effector. IKPy is precise (up to 7 digits after the decimal point), fast (7 to 50 milliseconds, depending on the precision of the model), and has the option to compute for every existing robot the IK for position or orientation only, or for both combined. Although IKPy was selected for this implementation, in other examples another kinematic solver could be used (e.g., IKFast).

The generation of the Webots world file, as described above with regard to the third step of phase 110, was implemented in B-Prolog, a logic programming platform. B-Prolog is an implementation of the Prolog programming language and was selected because: 1) it has an inherent reasoner that allows automated inference using unification, backtracking, and rewriting techniques, 2) it is compatible with C and Java programming languages, which enables bi-directional interface with procedural and object-oriented programming, respectively, for application development, and 3) it provides continuity and direct transfer of data from the BIM design models because the information extraction algorithms were created using B-Prolog. The generation of the Webots world file is not dependent on any programming languages. In other words, the simulation world file may, in other implementations, be generated using any other programming languages such as Python or Java.

The example implementation described here was conducted on a Windows 10 (64-bit) laptop with an Intel® Core i7-9750H CPU @ 2.60 GHz processor, 16 GB of Random Access Memory (RAM), and a NVIDIA® GeForce® GTX 1650 graphics card, which exceeds the minimum requirements specified for Webots.

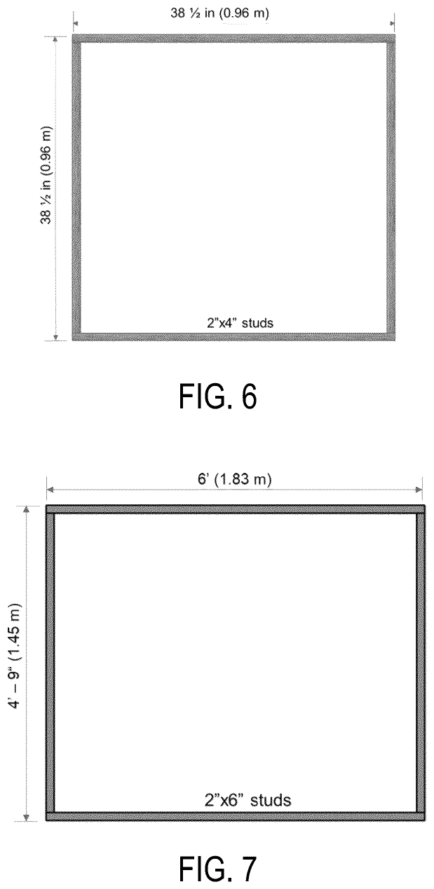

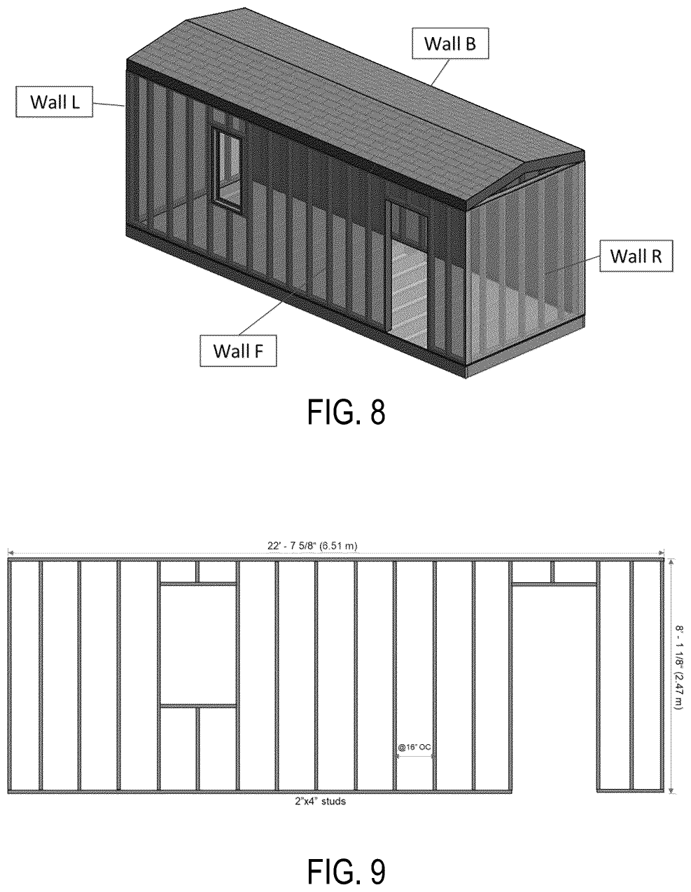

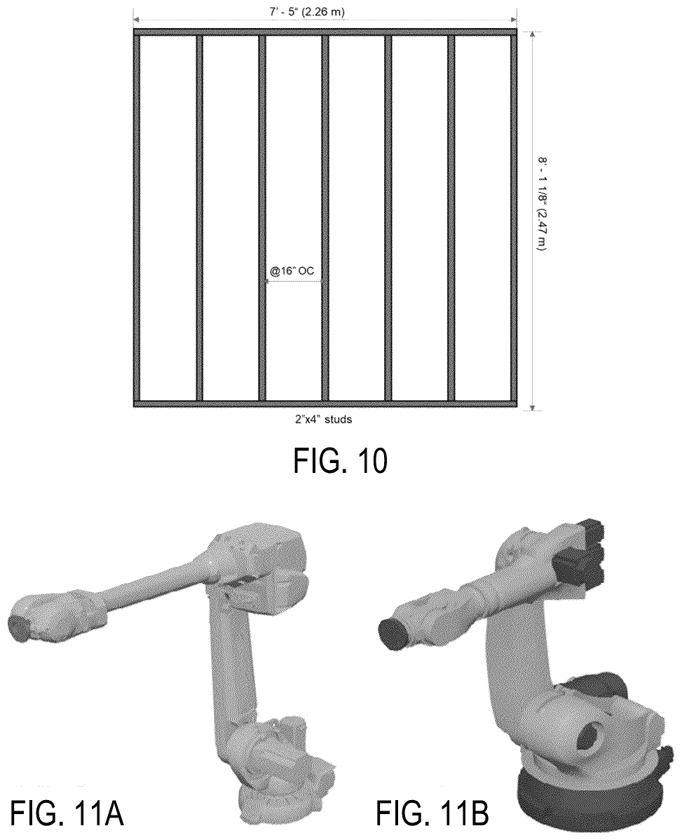

Three BIM design models were created and used as test cases in the example implementation following the method 100. The test cases consist of 1) a square frame of a 3-by-3-foot opening with 2″×4″ elements (see FIG. 6), 2) a rectangular frame with 2″×6″ elements (see FIG. 7), and 3) a wood structure that consists of 4 exterior walls (see FIG. 8). The height of the wall frames is 8 feet with intermediate studs spaced at every 16 inches on center. The stud size of the frames is 2″×4″. The BIM design models were created in Autodesk Revit (version 2019). The dimensions for each test model are shown in FIGS. 6, 7, 9, and 10, respectively.

The BIM data (i.e., in phase 102 of FIG. 1) extracted and derived from the three test cases (BIM design models) were used as input in the subsequent phases. The data extraction was performed by decomposing the structure (BIM design models) into individual components (i.e., wall frames) for each wall. Meanwhile for each wall frame, the corresponding studs (represented as IFC columns) and plates (represented as IFC beams) were grouped to the corresponding component (e.g., walls). In addition to the grouping of the elements, the assembly sequence of each element was automatically defined for each wall frame based on its spatial relationship. This extracted and derived information of the components from the BIM design model serve as input to the simulation of wall frames assembly. As previously mentioned, a logic-based method was implemented in B-Prolog to analyze and derive the BIM data.

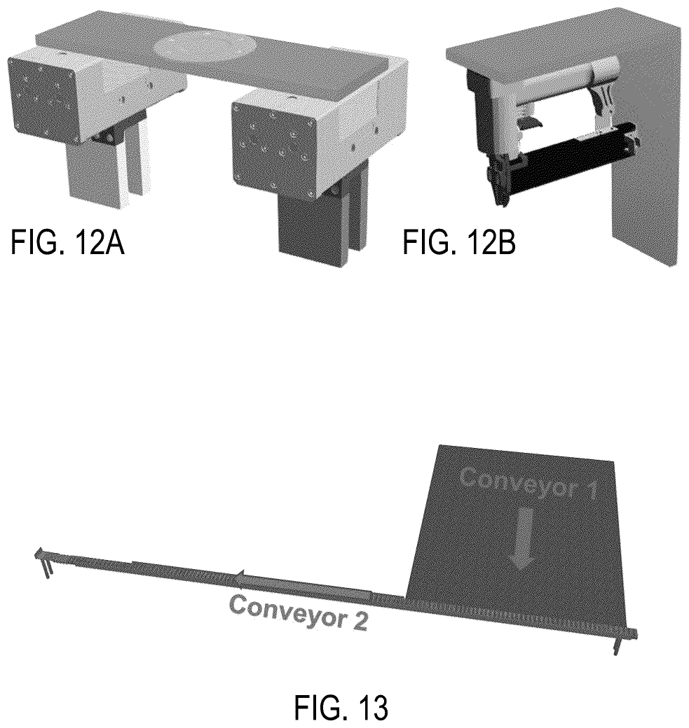

The selected components of the robotic system (i.e., in phase 104 of FIG. 1) are illustrated in FIGS. 11A-13. The ABB IRB 4600/40 (FIG. 11A) and KUKA KR 150-2 (FIG. 11B) robots were selected for the simulation because of their reach (2.55 m and 2.70 m, respectively) and payload capacity (40 kg and 150 kg, respectively). For the end-effector, two parallel grippers were used for the stable grasping of the construction materials (i.e., studs) in the framing operations (FIG. 12A). In addition, a nailing gun model was used for the fastening of the wood elements during the nailing operations (FIG. 12B).

Two conveyors were created to transport and feed the wood elements (i.e., studs) to the robot for the assembly process (FIG. 13). The first conveyor (Conveyor 1) is used to hold the elements that are instantiated in the simulation world. Conveyor 1 transfers each element (blue arrow) to the second conveyor (Conveyor 2). Then, the element continues to travel (red arrow) until it reaches the end of the Conveyor 2 (far left), where the robot picks up the elements for the framing process. This mechanism allows a constant influx of materials for the assembly process. For the assembly and nailing process, the factory floor is used as a fixture.

The sensors used in this robotic system include rotational and translational sensors, which are embedded in the rotational joint of the robot and in the translational joint of the end-effector's gripper fingers, respectively. In addition, a touch sensor is utilized in the second conveyor to notify the robot through radio frequency signals when an element is available for pick up at the end of the conveyor tray. In the robot, a receiver sensor is used to capture the signal emitted by the touch sensor. Once a signal is received, the robot starts the framing operations according to the framing subroutine.

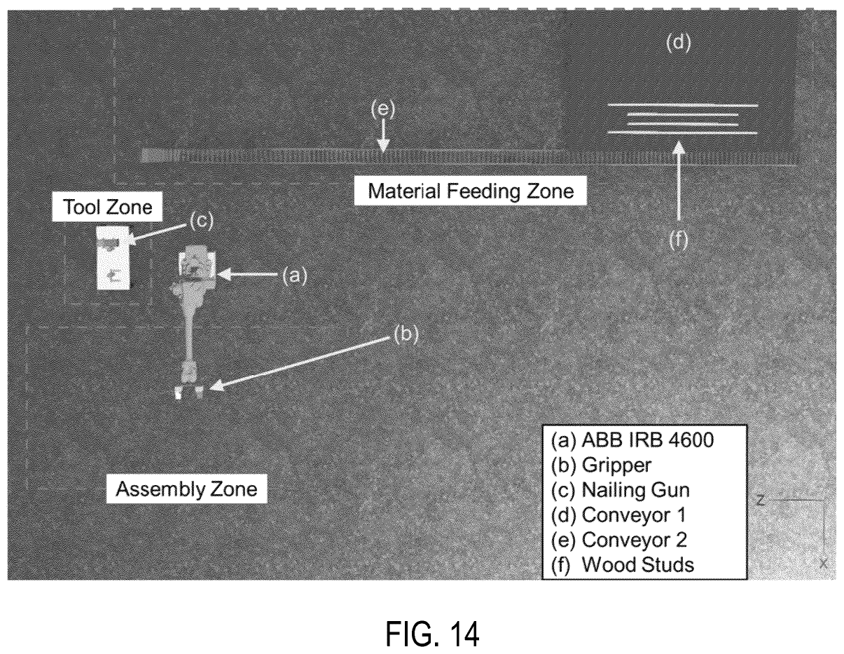

The models of the construction materials (i.e., 2×4 and 2×6) were created in the simulation environment (i.e., in phase 106 of FIG. 1). The length for the 2×4 and 2×6 models was one meter, which may then be adjusted during the mapping process according to the BIM design models. In addition, each component of the robotic system was created and/or imported in the simulation environment. Following that, the studs and the components of the robotic system were aggregated into assemblies. In Webots, the file format .proto is used to represent an assembly, which stores all the information of a 3D asset. Lastly, once the 3D models were added, each component of the robotic system was organized and positioned in the simulation environment (world) as shown in FIG. 14.

In the construction operations and control system definition phase (i.e., phase 108 of FIG. 1), knowledge from the construction and robotics domains were applied to support the development of the simulation. Accordingly, the subroutines for the framing and nailing operations were defined and created for the selected robots and coded (in Python) in the controller of the robot. Regarding the type of robot controller, supervisor was selected. A supervisor in Webots is a set of functions that allow the support module (i.e., IK function) to access input information and parameters of the robot during the simulation.

In addition to the framing and nailing subroutines, the conveyors were programmed to perform the feeding operations of the construction materials. The speeds of the conveyors were set at a constant value, 0.05 meter per second (m/s) and 2 meter per second (m/s) for conveyor 1 and conveyor 2, respectively. The operation of the conveyor system starts by feeding a construction element. Once the first element reached the end of the second conveyor, it triggers the touch sensor to send a signal to stop the movement of both conveyors and to initiate the construction operations by the robot. The conveyors resume operation after the transported element is picked up by the robot. This process continues until the last wood stud element is successfully transported for the framing operations. After the framing operations were completed, the nailing operations were initiated by the nailing subroutines.

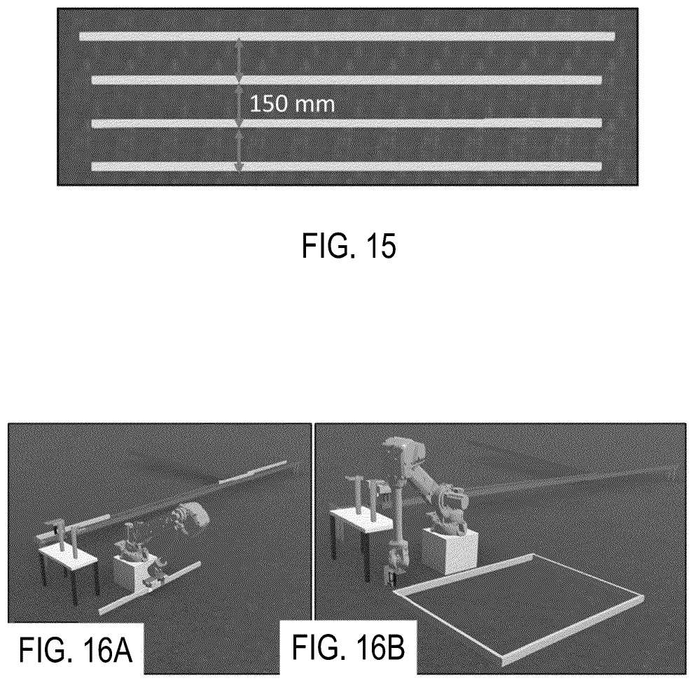

Webots implements a set of nodes as the core of the model structure in the Webots world files. The set of nodes used are partly derived from the VRML97 standard while other nodes are specific to Webots. By following the syntax of this model structure, Webots world files that contain all the model assets, assemblies, properties, and layout configurations of the robotic system components, were generated using rules developed in B-Prolog. During the simulation generation process (i.e., phase 110 of FIG. 1), the BIM elements were matched to the stud models of Webots, which were previously created according to the process detailed above with regard to the first step of phase 106) (Create the models of the construction materials). Following that, the matched studs were instantiated in the first conveyor with a spacing between elements set to 150 mm to allow the transfer of the studs from the first to the second conveyor without colliding with adjacent studs (see FIG. 15).

Next, the execution of the simulation initiated automatically when the Webots world file was loaded. In the simulation, the robotic system executed the assembly process based on the framing and nailing subroutines and the input information provided by the BIM data. FIGS. 16A and 16B show snapshots of the ABB robot performing the framing and nailing operations, respectively.

The performance of the simulation was evaluated according to the categories defined in the evaluation phase (i.e., phase 112 of FIG. 1) of the methodology. The mapping and generation processes from BIM to Webots were comparatively verified. Following, the simulation of the assembly process was evaluated. During the simulation, the robotic system performed the assembly operations using the developed construction algorithms. After the assembly subroutines were executed, the assembled frames were visually inspected and compared to the BIM design models. For each adjustment made to any of the components of the robotic system, the assembly process was simulated again (following the methodology). This process makes the methodology iterative, which allows for continuous improvement, leading to the desired performance level and outcomes. In addition, collisions were also checked.

### Example Implementation Results

This example implementation was performed to test the methodology using BIM as input for the simulation of robotic systems in the assembly process of wood frames. The results of BIM integration and robotic system simulation are as follows.

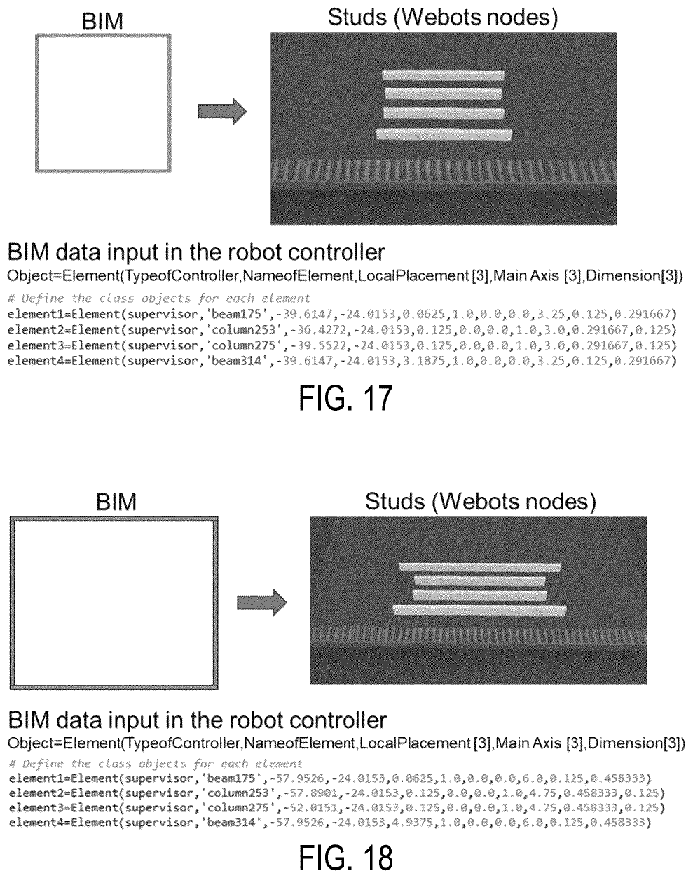

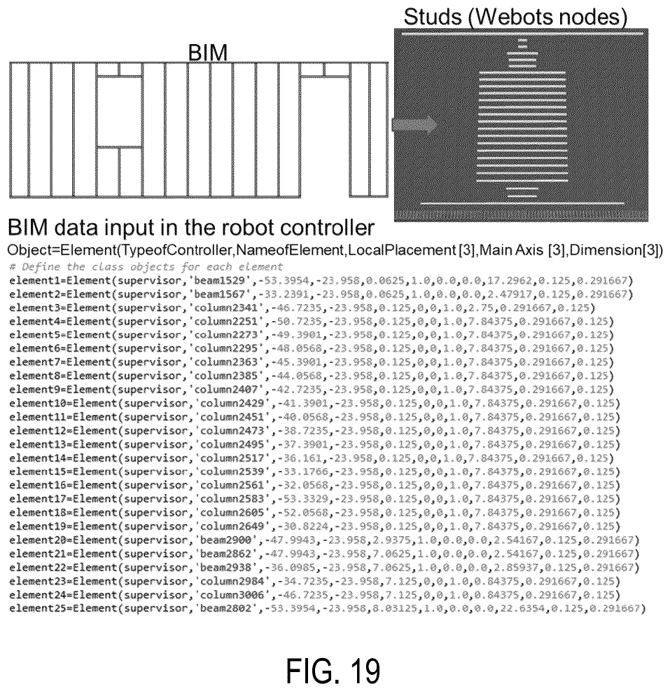

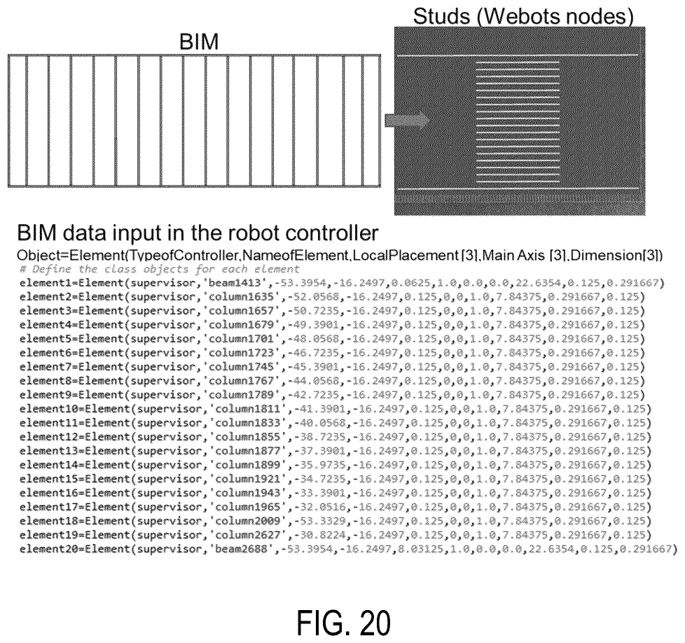

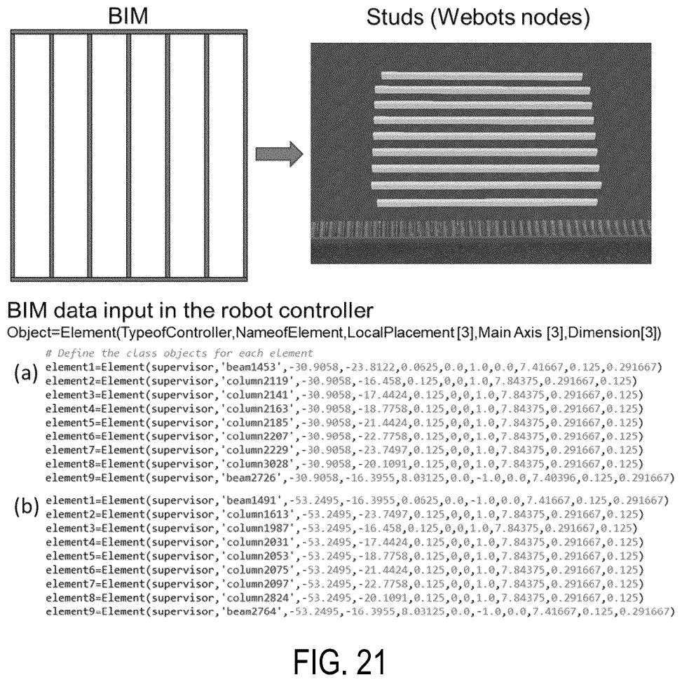

The integration of BIM and the robotic simulator Webots to simulate the assembly process of each test models was performed successfully as shown in FIGS. 17-21. In this example, for the framing process, stud objects of the wall frames, represented as IFC beams and IFC columns, were used. The results showed that the mapped elements in Webots were consistent and equivalent to those from the BIM design model. The automated generation process of the building elements in the simulation (as described above with regard to the fifth step of phase 108 and with regard to phase 110) is not only fast and accurate but also avoids the need of manually mapping and creating each lumber objects, which would be time consuming, cumbersome, and error prone.

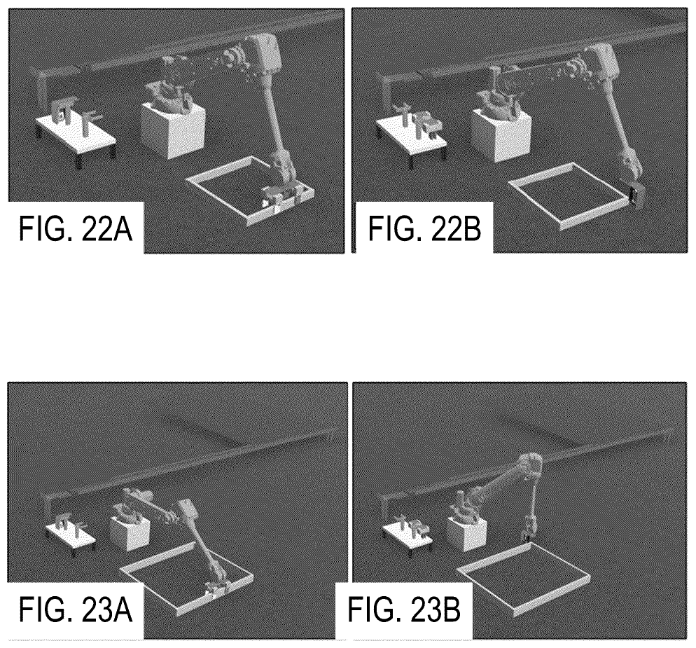

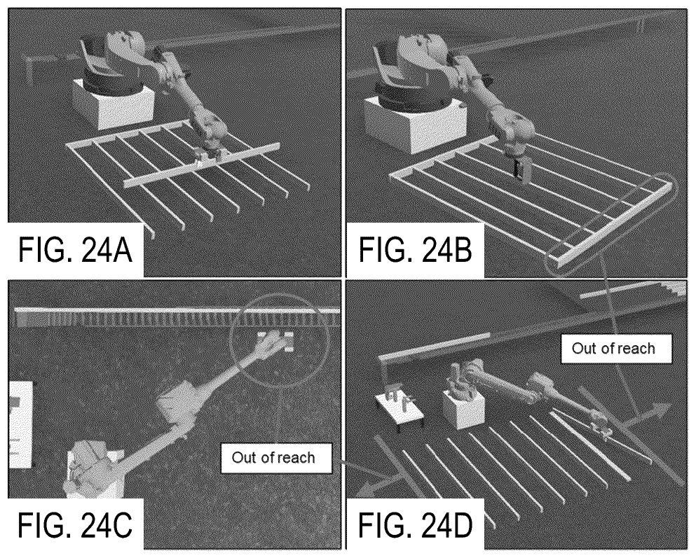

The developed methodology framework was implemented in the simulation of robotic assembly process of wood frames. The framing and nailing algorithms were successfully implemented using the two selected robots: IRB 4600 and KR 150-2. All the frames were successfully assembled and fastened except for the test model 3 as shown in FIGS. 22A-24D, respectively. The durations of the simulated framing and nailing processes of the test models were also measured. A summary of the results for the assembly process, including the material feeding process, of the three wood frames is presented in Table 4. For test model 3, the top plate was out of reach of the robot in the framing and fastening operations for Wall L and 653 Wall R as shown in FIGS. 24A and 24B, respectively. Similarly, the top and bottom plates as well as the five studs on both ends of the frame were out of reach of the robot for Wall F and B as shown in FIGS. 24C and 24D, respectively. Therefore, it was labeled as ‘Partial’ in the framing and nailing processes as shown in Table 4. In addition, the robotic system component corresponding to the failure of the framing and nailing operations, was identified as ‘Failed component’, which in this case was the robot itself. Note that the duration of the nailing process was not measured due to the premature failure of the nailing operation in the connections between bottom plate and the three internal studs (unable to find the solution of the IK to reach those nailing target locations).

TABLE 4
Simulation results of the automated framing and
nailing processes for the three test models

| | Material | | Time | Failed | | Time | Failed |
|---|---|---|---|---|---|---|---|
| Frame | feeding | Framing | (min) | component | Nailing | (min) | component |
| 1 | Completed | Completed | 2.22 | — | Completed | 1.33 | — |
| 2 | Completed | Completed | 2.23 | — | Completed | 1.52 | — |
| 3L | Completed | Partial | 4.53 | Robot | Partial | — | Robot |
| 3R | Completed | Partial | 4.50 | Robot | Partial | — | Robot |
| 3F | Completed | Partial | — | Robot | Partial | — | Robot |
| 3B | Completed | Partial | — | Robot | Partial | — | Robot |

Robotic automation in construction is an open-ended problem. As such, it is not bound to a unique solution, but rather multiple solutions could exist, in which each has its own implications. For instance, in an offsite construction facility, the selection of a robotic system depends on the constraints and factors such as the size of the manufacturing space and cost of the robotic system components, respectively. Therefore, different configurations of the robotic system components could have been selected in these example implementations instead of the ones presented above.

The method 100 may facilitate the evaluation of construction robotics and VDC in the AEC domain because it can be used to measure the productivity output of a robotic system and to analyze the behavior of a robotic system in a specific construction process. Also, the control system (algorithms and integration with BIM) from the simulated robots can be directly transferred to actual physical robots to facilitate their implementations.

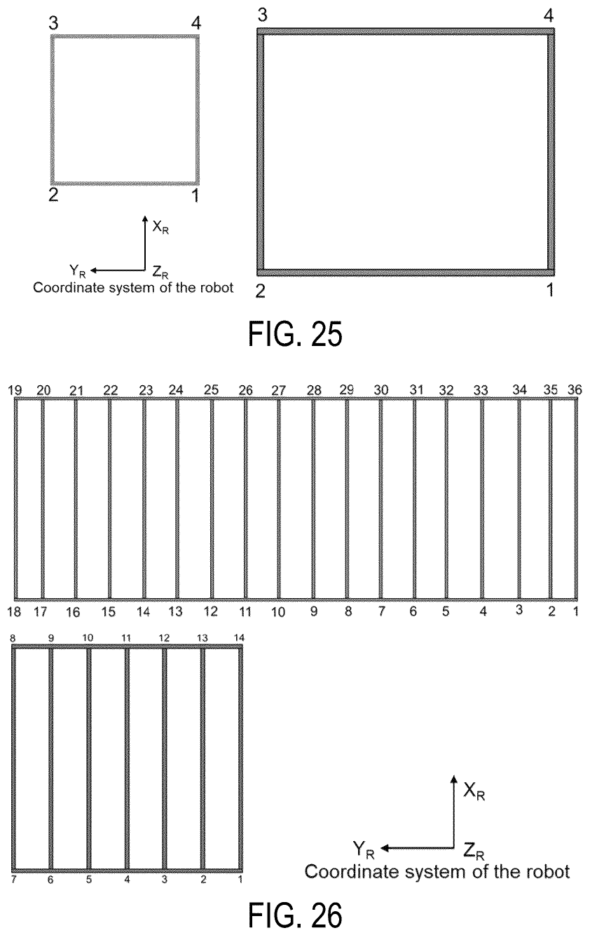

A test was performed to determine the performance of the nailing target locations as described above with regard to the second step of phase 108. The values of the nailing target locations determined using Eq. (1), Eq. (2), and Eq. (3), were verified by manually computing the nailing location values for each element using information from the simulation. The information used for the manually computed values include the position of the centroid and the dimensions of the elements relative to the coordinate system of the robot after the framing process took place. The comparison results for the test models 1 and 2 are presented in Table 5 and Table 6, respectively, where ‘Location’ refers to the connections points (FIG. 25). For the result of test model 3, the results are shown in Table 7 and Table 8 that correspond to the locations of the frames in Wall L and R, and Wall F and B, respectively, as shown in FIG. 26. The Nₓ, N_{y}, and N_{z} are the nailing target locations determined using the method 100; X, Y, and Z are the nailing locations that were manually computed; and x_{diff}, y_{diff}, and z_{diff} are the relative change (in percentage) of the two approaches. In Table 7, the y_{diff} for the location 4 and 11 was expressed in absolute difference instead of the relative change in percentage because the value of N_{y} was zero, yielding a relative change of 100%.

TABLE 5
Result of the validation for the nailing target location of test model 1

| | Method 100 (m) | | | | Manually Computed values (m) | | | | Relative change (%) | | | |
|---|---|---|---|---|---|---|---|---|---|---|---|---|
| Location | Nₓ | N_{y} | N_{z} | | X | Y | Z | | x_{diff} | y_{diff} | z_{diff} | |
| 1 | 0.881 | −0.476 | 0.029 | 0.059 | 0.879 | −0.474 | 0.029 | 0.059 | 0.17 | 0.42 | 0.64 | 0.94 |
| 2 | 0.881 | 0.476 | 0.029 | 0.059 | 0.879 | 0.474 | 0.029 | 0.059 | 0.17 | 0.40 | 0.64 | 0.94 |
| 3 | 1.872 | 0.476 | 0.029 | 0.059 | 1.870 | 0.474 | 0.029 | 0.059 | 0.08 | 0.40 | 0.64 | 0.94 |
| 4 | 1.872 | −0.476 | 0.029 | 0.059 | 1.870 | −0.474 | 0.029 | 0.059 | 0.08 | 0.42 | 0.64 | 0.94 |

TABLE 6
Result of the validation for the nailing target location of test model 2

| | Method 100 (m) | | | | Manually Computed values (m) | | | | Relative change (%) | | | |
|---|---|---|---|---|---|---|---|---|---|---|---|---|
| Location | Nₓ | N_{y} | N_{z} | | X | Y | Z | | x_{diff} | y_{diff} | z_{diff} | |
| 1 | 0.731 | −0.895 | 0.047 | 0.093 | 0.735 | −0.896 | 0.046 | 0.092 | −0.56 | −0.05 | 2.22 | 0.74 |
| 2 | 0.731 | 0.895 | 0.047 | 0.093 | 0.735 | 0.896 | 0.046 | 0.092 | −0.56 | −0.08 | 2.22 | 0.74 |
| 3 | 2.255 | 0.895 | 0.047 | 0.093 | 2.259 | 0.896 | 0.046 | 0.092 | −0.19 | −0.08 | 2.22 | 0.74 |
| 4 | 2.255 | −0.895 | 0.047 | 0.093 | 2.259 | −0.896 | 0.046 | 0.092 | −0.19 | −0.05 | 2.22 | 0.74 |

TABLE 7
Result of the validation for the nailing target location of test model 3 Wall L and R

| | Method 100 (m) | | | | Manually Computed values (m) | | | | Relative change (%) | | | |
|---|---|---|---|---|---|---|---|---|---|---|---|---|
| Location | Nₓ | N_{y} | N_{z} | | X | Y | Z | | x_{diff} | y_{diff} | z_{diff} | |
| 1 | 0.531 | −1.111 | 0.029 | 0.059 | 0.530 | −1.110 | 0.029 | 0.058 | 0.26 | 0.11 | 2.29 | 1.44 |
| 2 | 0.531 | −0.811 | 0.029 | 0.059 | 0.530 | −0.813 | 0.029 | 0.058 | 0.26 | −0.24 | 2.46 | 1.53 |
| 3 | 0.531 | −0.405 | 0.029 | 0.059 | 0.530 | −0.407 | 0.029 | 0.058 | 0.26 | −0.52 | 2.46 | 1.53 |
| 4 | 0.531 | 0.002 | 0.029 | 0.059 | 0.530 | 0.000 | 0.029 | 0.058 | 0.26 | 0.002 | 2.46 | 1.53 |
| 5 | 0.531 | 0.408 | 0.029 | 0.059 | 0.530 | 0.404 | 0.029 | 0.058 | 0.26 | 0.95 | 2.28 | 1.44 |
| 6 | 0.531 | 0.814 | 0.029 | 0.059 | 0.530 | 0.810 | 0.029 | 0.058 | 0.26 | 0.51 | 2.58 | 1.59 |
| 7 | 0.531 | 1.111 | 0.029 | 0.059 | 0.530 | 1.110 | 0.029 | 0.058 | 0.26 | 0.09 | 2.58 | 1.59 |
| 8 | 2.998 | 1.111 | 0.029 | 0.059 | 3.006 | 1.212 | 0.029 | 0.058 | −0.28 | −8.30 | 2.58 | 1.59 |
| 9 | 2.998 | 0.814 | 0.029 | 0.059 | 2.987 | 0.813 | 0.029 | 0.058 | 0.36 | 0.22 | 2.58 | 1.59 |
| 10 | 2.998 | 0.408 | 0.029 | 0.059 | 2.987 | 0.406 | 0.029 | 0.058 | 0.36 | 0.47 | 2.58 | 1.59 |
| 11 | 2.998 | 0.002 | 0.029 | 0.059 | 2.987 | 0.000 | 0.029 | 0.058 | 0.36 | −0.001 | 2.58 | 1.59 |
| 12 | 2.998 | −0.405 | 0.029 | 0.059 | 2.987 | −0.406 | 0.029 | 0.058 | 0.36 | 0.28 | 2.58 | 1.59 |
| 13 | 2.998 | −0.811 | 0.029 | 0.059 | 2.987 | −0.813 | 0.029 | 0.058 | 0.36 | 0.16 | 2.58 | 1.59 |
| 14 | 2.998 | −1.111 | 0.029 | 0.059 | 2.987 | −1.212 | 0.029 | 0.058 | 0.36 | −8.31 | 2.58 | 1.59 |

TABLE 8
Result of the validation for the nailing target location of test model 3 Wall F and B

| | Method 100 (m) | | | | Manually Computed values (m) | | | | Relative change (%) | | | |
|---|---|---|---|---|---|---|---|---|---|---|---|---|
| Location | Nₓ | N_{y} | N_{z} | | X | Y | Z | | x_{diff} | y_{diff} | z_{diff} | |
| 1 | 0.531 | −3.430 | 0.029 | 0.059 | 0.530 | −3.459 | 0.029 | 0.058 | 0.26 | −0.83 | 2.58 | 1.59 |
| 2 | 0.531 | −3.041 | 0.029 | 0.059 | 0.530 | −3.053 | 0.029 | 0.058 | 0.26 | −0.37 | 2.58 | 1.59 |
| 3 | 0.531 | −2.635 | 0.029 | 0.059 | 0.530 | −2.646 | 0.029 | 0.058 | 0.26 | −0.43 | 2.58 | 1.59 |
| 4 | 0.531 | −2.229 | 0.029 | 0.059 | 0.530 | −2.240 | 0.029 | 0.058 | 0.26 | −0.51 | 2.58 | 1.59 |
| 5 | 0.531 | −1.822 | 0.029 | 0.059 | 0.530 | −1.834 | 0.029 | 0.058 | 0.26 | −0.62 | 2.58 | 1.59 |
| 6 | 0.531 | −1.416 | 0.029 | 0.059 | 0.530 | −1.427 | 0.029 | 0.058 | 0.26 | −0.79 | 2.46 | 1.53 |
| 7 | 0.531 | −1.010 | 0.029 | 0.059 | 0.530 | −1.021 | 0.029 | 0.057 | 0.26 | −1.13 | 2.58 | 4.54 |
| 8 | 0.531 | −0.603 | 0.029 | 0.059 | 0.530 | −0.615 | 0.029 | 0.058 | 0.26 | −1.89 | 2.46 | 1.59 |
| 9 | 0.531 | −0.197 | 0.029 | 0.059 | 0.530 | −0.209 | 0.029 | 0.058 | 0.26 | −5.66 | 2.46 | 1.59 |
| 10 | 0.531 | 0.210 | 0.029 | 0.059 | 0.530 | 0.196 | 0.029 | 0.058 | 0.26 | 6.67 | 2.46 | 1.59 |
| 11 | 0.531 | 0.616 | 0.029 | 0.059 | 0.530 | 0.602 | 0.029 | 0.058 | 0.26 | 2.25 | 2.46 | 1.59 |
| 12 | 0.531 | 1.022 | 0.029 | 0.059 | 0.530 | 1.009 | 0.029 | 0.058 | 0.26 | 1.36 | 2.58 | 1.59 |
| 13 | 0.531 | 1.429 | 0.029 | 0.059 | 0.530 | 1.415 | 0.029 | 0.058 | 0.26 | 0.98 | 2.58 | 1.59 |
| 14 | 0.531 | 1.860 | 0.029 | 0.059 | 0.530 | 1.821 | 0.029 | 0.058 | 0.26 | 2.15 | 2.58 | 1.59 |
| 15 | 0.531 | 2.241 | 0.029 | 0.059 | 0.530 | 2.228 | 0.029 | 0.058 | 0.26 | 0.62 | 2.58 | 1.59 |
| 16 | 0.531 | 2.648 | 0.029 | 0.059 | 0.530 | 2.634 | 0.029 | 0.058 | 0.26 | 0.52 | 2.58 | 1.59 |
| 17 | 0.531 | 3.056 | 0.029 | 0.059 | 0.530 | 3.040 | 0.029 | 0.058 | 0.26 | 0.50 | 2.58 | 1.59 |
| 18 | 0.531 | 3.430 | 0.029 | 0.059 | 0.530 | 3.447 | 0.029 | 0.058 | 0.26 | −0.48 | 2.58 | 1.59 |
| 19 | 2.998 | −3.430 | 0.029 | 0.059 | 3.006 | −3.459 | 0.029 | 0.058 | −0.28 | 0.83 | 2.58 | 1.59 |
| 20 | 2.998 | −3.041 | 0.029 | 0.059 | 3.006 | −3.053 | 0.029 | 0.058 | −0.28 | −0.37 | 2.58 | 1.59 |
| 21 | 2.998 | −2.635 | 0.029 | 0.059 | 3.006 | −2.646 | 0.029 | 0.058 | −0.28 | −0.43 | 2.58 | 1.59 |
| 22 | 2.998 | −2.229 | 0.029 | 0.059 | 3.006 | −2.240 | 0.029 | 0.058 | −0.28 | −0.51 | 2.58 | 1.59 |
| 23 | 2.998 | −1.822 | 0.029 | 0.059 | 3.006 | −1.834 | 0.029 | 0.058 | −0.28 | −0.62 | 2.58 | 1.59 |
| 24 | 2.998 | −1.416 | 0.029 | 0.059 | 3.006 | −1.427 | 0.029 | 0.058 | −0.28 | −0.79 | 2.58 | 1.59 |
| 25 | 2.998 | −1.010 | 0.029 | 0.059 | 3.006 | −1.021 | 0.029 | 0.058 | −0.28 | −1.13 | 2.58 | 1.59 |
| 26 | 2.998 | −0.603 | 0.029 | 0.059 | 3.006 | −0.615 | 0.029 | 0.058 | −0.28 | −1.89 | 2.58 | 1.59 |
| 27 | 2.998 | −0.197 | 0.029 | 0.059 | 3.006 | −0.196 | 0.029 | 0.058 | −0.28 | 0.79 | 2.58 | 1.59 |
| 28 | 2.998 | 0.210 | 0.029 | 0.059 | 3.006 | 0.209 | 0.029 | 0.058 | −0.28 | 0.44 | 2.58 | 1.59 |
| 29 | 2.998 | 0.616 | 0.029 | 0.059 | 3.006 | 0.602 | 0.029 | 0.058 | −0.28 | 2.25 | 2.58 | 1.59 |
| 30 | 2.998 | 1.022 | 0.029 | 0.059 | 3.006 | 1.009 | 0.029 | 0.058 | −0.28 | 1.36 | 2.58 | 1.59 |
| 31 | 2.998 | 1.429 | 0.029 | 0.059 | 3.006 | 1.415 | 0.029 | 0.058 | −0.28 | 0.98 | 2.58 | 1.59 |
| 32 | 2.998 | 1.860 | 0.029 | 0.059 | 3.006 | 1.821 | 0.029 | 0.058 | −0.28 | 2.15 | 2.58 | 1.59 |
| 33 | 2.998 | 2.241 | 0.029 | 0.059 | 3.006 | 2.228 | 0.029 | 0.058 | −0.28 | 0.62 | 2.58 | 1.59 |
| 34 | 2.998 | 2.648 | 0.029 | 0.059 | 3.006 | 2.634 | 0.029 | 0.058 | −0.28 | 0.52 | 2.58 | 1.59 |
| 35 | 2.998 | 3.056 | 0.029 | 0.059 | 3.006 | 3.040 | 0.029 | 0.058 | −0.28 | 0.50 | 2.58 | 1.59 |
| 36 | 2.998 | 3.430 | 0.029 | 0.059 | 3.006 | 3.447 | 0.029 | 0.058 | −0.28 | −0.48 | 2.58 | 1.59 |

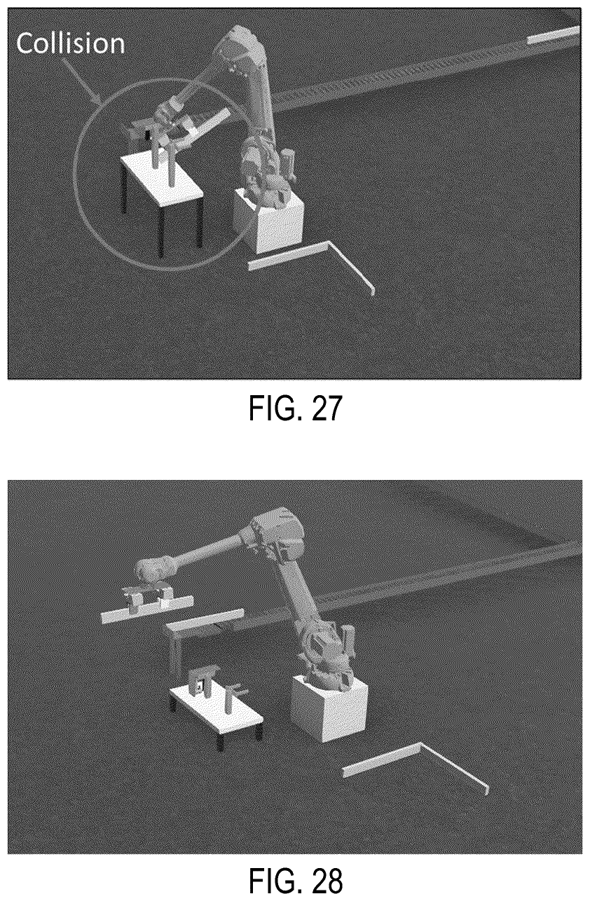

Similar to clash detection in the building design development (e.g., MEP and structural systems), the simulation of robotic system can be used to detect collisions between different components within the system or any nearby objects, which takes both the spatial and temporal dimensions into consideration. Such collisions can interfere with the operations of the robotic system components. During the framing operations, a collision between the robot and the tool table was identified as shown in FIG. 27. The height of the legs of the tool table was adjusted to avoid collisions in subsequent simulations of the assembly process (FIG. 28).

The method 100 was compared to manual operations in time efficiency. The process of manually extracting the needed information to simulate the assembly process was performed according to the six steps specified in Table 9. The manual process consists of the extraction of the relevant information from the BIM design models. The time performance of the methodology refers to the time taken to generate the simulation file (i.e., Webots world) starting from the BIM authoring tool as described above with regard to the simulation generation and execution operations.

TABLE 9
List of steps for the manual extraction process

| # | Tasks |
|---|---|
| 1 | Identify all relevant elements (i.e., lumbers) of the frames and their attributes from the |
| | BIM design model. |
| 2 | Extract the dimensions, main axis, names, and placement locations for all elements. |
| 3 | Compute the position of the center of gravity of the elements. |
| 4 | Create the elements (Webots objects) in the simulation environment based on the |
| | attributes extracted. |
| 5 | Position the elements on the conveyor 1 in the simulation environment. |
| 6 | Input the data in the controller of the robot for the framing and nailing operations. |

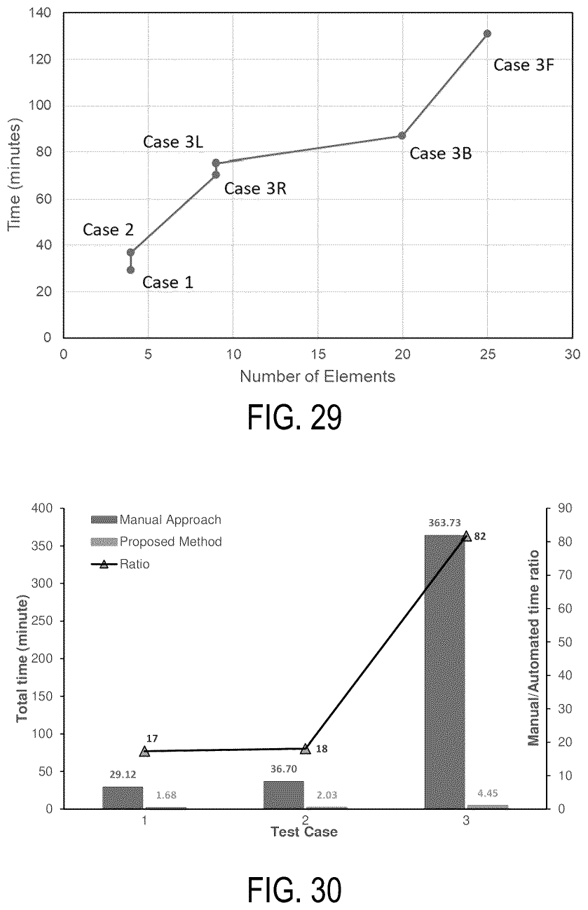

To compare the method 100 against the manual process, the time consumption of both approaches was recorded. The time for the manual process was recorded and presented in Table 10. The time of the manual process was plotted against the number (e.g., studs) of elements present in a frame model (FIG. 29). The trend also shows an increase in the total time consumption when the complexity of the model being tested increases. Specifically, the time for the developed method were 1.68, 2.03, and 4.45 minutes for test models 1, 2, and 3, respectively.

TABLE 10
Time performance of the manual process

| | Time in minutes | | | | | |
|---|---|---|---|---|---|---|
| | Case | Case | Case | Case | Case | Case |
| Task | 1 | 2 | 3F | 3B | 3L | 3R |
| Extract dimensions | 3.3 | 4.7 | 20.7 | 14.9 | 10.3 | 8.3 |
| Extract main axis | 1.6 | 3.1 | 11.8 | 7.4 | 10.7 | 6.3 |
| Extract names | 1.0 | 0.9 | 8.3 | 5.6 | 4.1 | 4.6 |
| Extract placement | 14.8 | 15.7 | 53.5 | 38.1 | 31.1 | 31.2 |
| locations | | | | | | |
| Creation of the | 4.8 | 7.7 | 16.1 | 7.9 | 11.1 | 10.3 |
| elements | | | | | | |
| Input information | 3.6 | 4.6 | 20.6 | 13.1 | 8.0 | 9.7 |
| Total | 29.1 | 36.7 | 131.0 | 87.0 | 75.4 | 70.4 |

The time comparison results of both approaches on the three test cases are shown in FIG. 29. The results in FIG. 30 indicate that the proposed approach is on average 39 times faster than the manual approach for the three tested cases, 17, 18, and 82 times for test models 1, 2, and 3, respectively. As shown for test model 3 in FIG. 30, the larger and more complex a BIM design model is, the greater the time saving becomes. Another advantage of the approach exemplified by the method 100 is that it can generate simulation files automatically, which therefore reduces the errors when there are changes in the building design.

The method 100 provides an integration framework to bridge the gap between building design and construction phases through a BIM-robotics workflow for a greater collaboration and coordination compared to comparative examples (i.e., working in siloes) in offsite construction. Additionally, the method 100 includes practical knowledge from the robotic and construction domains and implementation details of robotic systems to support a wider adoption of construction robotics in the AEC domain. The method 100 provides a tool to generate required information automatically from BIM as input for robotic system operational analysis to support wood frame assembly automation in offsite construction. Moreover, the simulation-based approach using robotic simulation allows the analysis of industrial arm (i.e., manipulator-type robots) in the framing and fastening operations during the preconstruction phase to facilitate the planning and analysis of automation strategies. In addition, it serves as a blueprint for researchers and practitioners to adopt and reuse for analyzing other types of robotic systems and/or construction workflows. Moreover, the use of IFC-based BIM in the integration with an open-source robotic simulator (e.g., Webots), promotes and contributes to solving the interoperability of information exchange in the AEC industry.

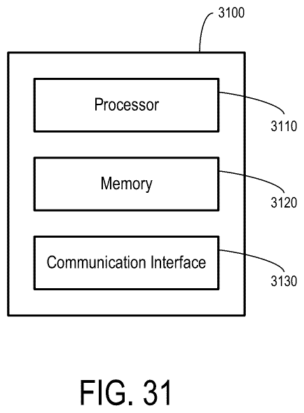

FIG. 31 illustrates an example of a BIM simulation system 3100 that may implement the methodologies described herein. The BIM simulation system 3100 includes a processor 3110, a memory 3120, and a communication interface 3130.

The processor 3110 comprises processing circuitry configured to execute one or more operating routines stored in the memory 3120 or in another storage medium or storage device. The processor 3110 may comprise, for example, any one or more of the circuitry described above, including but not limited to one or more CPUs, GPUs, ASICS, FPGAs, microcontrollers, DSPs, other processing circuitry, or combinations thereof. In some implementations, the processor 3110 may include one or more processing units, each of which includes one or more processing cores. In such implementations, any one or more of the individual processing units and/or cores may perform any one or more subroutines of the one or more operating routines, either in tandem or individually. The processor 3110 may, in some implementations, be partially or wholly external to the BIM simulation system 3100, for example to implement cloud processing.

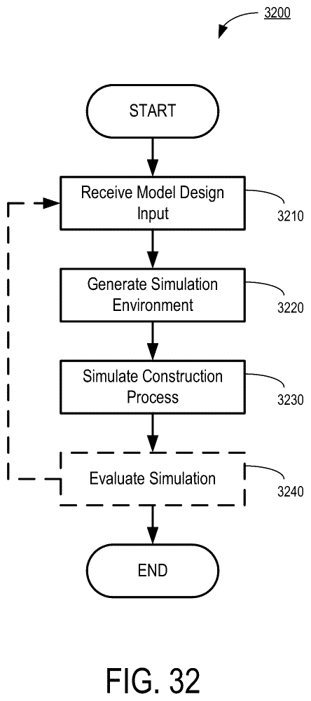

The memory 3120 comprises a storage medium and is configured to store instructions that may be executed by a processor, such as the processor 3110. The memory 3120 may, in some implementations, be partly or wholly external to the BIM simulation system 3100, for example to implement cloud storage. The memory 3120 may include non-transitory storage components (e.g., hard disks, RAM, removable storage media, etc.) and/or transitory storage components (e.g., carrier signals). In one implementation, the memory 3120 is a non-transitory computer-readable medium that stores instructions that, when executed by the processor 3110 (or another processing component), causes the system 3100 to perform various operations, such as those described herein. FIG. 32 illustrates one example of a method 3200 that may be performed in response to execution of the instructions. The operations of method 3200 may be similar to or correspond to some of the phases discussed above with regard to methodology 100 of FIG. 1.

As shown in FIG. 32, the method 3200 begins with an operation 3210 of receiving a model design input. The model design input may include at least one of a BIM design input parameter or a robotic system input parameter. At the operation 3220, the method 3200 generates a virtual simulation environment based on the model design input. Operation 3220 may be performed automatically in response to operation 3210 (e.g., automatically upon completion of operation 3210). In some implementations, operation 3220 includes sub-operations of generating a model of a construction material and/or generating a model of a robotic system, which itself may include generating models of one or more (e.g., a plurality of) components of the robotic system, aggregating the models of the components into at least one assembly, and defining a layout of the robotic system.

In some implementations, the method 3200 (e.g., operation 3220) may further include determining a construction operation to be performed in the simulation environment and defining a behavior of the robotic system based on the construction operation. In such implementations, determining the construction operation may include determining at least one target location for a framing operation, determining at least one target location for a nailing operation, defining a placement orientation relative to the robotic system in the simulation environment, generate at least one subroutine for the robotic system, providing control data to a controller of the robotic system, and defining a behavior for a component of the robotic system.

Next, at operation 3230, the method 3200 simulates a construction process by the robotic system in the simulation environment. Operation 3230 may be performed automatically in response to operation 3220 (e.g., automatically upon completion of operation 3220). In some implementations, operation 3230 includes sub-operations of mapping one or more (e.g., a plurality of) BIM building elements to a plurality of construction materials and defining an initial pose (e.g., position and orientation) of the construction materials in the simulation environment.

After performing the simulation, in certain examples the method 3200 includes an operation 3240 of evaluating the simulated construction process. Based on the result of the operation of evaluating (e.g., if it is determined that the simulation included an error or deficiency), the method 3200 may return to operation 3210 to perform one or more additional iterations of operations 3210-3230 (e.g., based on modified model design input parameters).

Method 3200 may be used to simulate a construction process which includes assembling a frame using at least one plate and at least one stud. The assembly may use at least one nail. The simulated construction process may involve a simulated robotic system, which in turn comprises robotic manipulator, a modular (e.g., replaceable or interchangeable) end effector, a material handling device, and a sensor.

The operations and sub-operations of method 3200 may be performed in an order different from that expressly illustrated in FIG. 32 and described above. In some examples, certain operations or sub-operations may be performed in series, in parallel, or both on the same or different processors.

Returning to FIG. 31, the communication interface 3130 may be or include any components configured to provide for the transfer of data and/or control signals between the system 3100 and other devices or entities. For example, the communication interface 3130 may include hardware (e.g., communication ports) and/or software or firmware (e.g., programs to implement communication protocols) and may be configured to provide for either wireless (e.g., using Wi-Fi®, Bluetooth®, Near Field Communication, combinations thereof, etc.) or wired (e.g., Ethernet, Universal Serial Bus, combinations thereof, etc.) communication.

Herein, systems and methods to automatically generate simulations of robotic automation for the assembly process of wood framing construction using BIM data as input have been presented. The framework of the methodology integrates BIM and robotics to simulate the assembly process in the context of offsite wood construction. The methodology was validated in three BIM test cases with different configurations of robotic systems, including two industrial robots (ABB IRB 4600 and KUKA KR 150-2), in the framing and fastening operations. Although both robots are industrial arms, they have different parameters (e.g., joint limits, link lengths, base diameter) to analyze in the simulations. For example, the diameter of the KUKA KR 150-2's base was larger than that of the ABB IRB 4600, which required a larger offset distance in the x-axis. These differences were appropriately considered through the variation of the parameters, and successfully simulated. In addition, the proposed approach suggests that assembly operations of offsite frame construction can be simulated and analyzed for using different robotic systems.

The presented methodology addresses the adoption challenges of construction robotics in at least three ways. First, knowledge and concepts from the robotics and construction domains were applied together in the development of the simulation-based approach and algorithms for the assembly operations. Second, data from BIM design model are used as input in the simulation-based methodology, harnessing the synergy and value of BIM and robotic simulation in the design and construction phases. Third, stakeholders can have a better conceptualization of the benefits and limitations of automation in the assembly of wood components in this simulation environment. The proposed simulation-based approach serves as a tool for researchers and practitioners to develop simulations for construction applications using different robotic systems.

Other examples and uses of the disclosed technology will be apparent to those having ordinary skill in the art upon consideration of the specification and practice of the invention disclosed herein. The specification and examples given should be considered exemplary only, and it is contemplated that the appended claims will cover any other such embodiments or modifications as fall within the true scope of the invention.

The Abstract accompanying this specification is provided to enable the United States Patent and Trademark Office and the public generally to determine quickly from a cursory inspection the nature and gist of the technical disclosure and in no way intended for defining, determining, or limiting the present invention or any of its embodiments.

What is claimed is:

1. A building information modeling (BIM) simulation system, comprising:
a processor; and
a memory storing instructions that, when executed by the processor, cause the system to perform operations comprising:
receiving a model design input, the model design input including at least one of a BIM design input parameter or a robotic system input parameter,
generating a virtual simulation environment based on the model design input,
simulating a construction process by a robotic system in the simulation environment.

2. The system of claim 1, the operations further comprising:
determining a construction operation to be performed in the simulation environment; and
defining a behavior of the robotic system based on the construction operation.

3. The system of claim 2, wherein the operation of determining comprises:
determining at least one target location for a framing operation;
determining at least one target location for a nailing operation;
defining a placement orientation relative to the robotic system in the simulation environment;
generate at least one subroutine for the robotic system;
providing control data to a controller of the robotic system; and
defining a behavior for a component of the robotic system.

4. The system of claim 1, wherein the operation of generating is automatically performed in response to the operation of receiving, and wherein the operation of simulating is automatically performed in response to the operation of generating.

5. The system of claim 1, wherein the operation of generating comprises:
generating a model of a construction material; and
generating a model of the robotic system, including generating models of a plurality of components of the robotic system, aggregating the models of the plurality of components into at least one assembly, and defining a layout of the robotic system.

6. The system of claim 1, wherein the operation of simulating comprises:
mapping a plurality of BIM building elements to a plurality of construction materials; and
defining an initial pose of the plurality of construction materials in the simulation environment.

7. The system of claim 1, wherein the construction process includes assembling a frame using at least one plate and at least one stud.

8. The system of claim 1, wherein the robotic system includes a robotic manipulator, a modular end effector, a material handling device, and a sensor.

9. The system of claim 1, the operations further comprising:
evaluating the simulated construction process.

10. The system of claim 9, the operations further comprising:
based on a result of the operation of evaluating, iteratively performing at least one additional instance of the operations of receiving, generating, and simulating.

11. A method of simulating a building information modeling (BIM) environment, the method comprising:
receiving a model design input, the model design input including at least one of a BIM design input parameter or a robotic system input parameter;
generating a virtual simulation environment based on the model design input; and
simulating a construction process by a robotic system in the simulation environment.

12. The method of claim 11, comprising:
determining a construction operation to be performed in the simulation environment; and
defining a behavior of the robotic system based on the construction operation.

13. The method of claim 12, wherein the operation of determining comprises:
determining at least one target location for a framing operation;
determining at least one target location for a nailing operation;
defining a placement orientation relative to the robotic system in the simulation environment;
generate at least one subroutine for the robotic system;
providing control data to a controller of the robotic system; and
defining a behavior for a component of the robotic system.

14. The method of claim 11, wherein the operation of generating is automatically performed in response to the operation of receiving, and wherein the operation of simulating is automatically performed in response to the operation of generating.

15. The method of claim 11, wherein the operation of generating comprises:
generating a model of a construction material; and
generating a model of the robotic system, including generating models of a plurality of components of the robotic system, aggregating the models of the plurality of components into at least one assembly, and defining a layout of the robotic system.

16. The method of claim 11, wherein the operation of simulating comprises:
mapping a plurality of BIM building elements to a plurality of construction materials; and
defining an initial pose of the plurality of construction materials in the simulation environment.

17. The method of claim 11, wherein the model input includes parameters derived by performing an automated logic representation and reasoning operation on a building design model.

18. The method of claim 11, wherein the robotic system includes a robotic manipulator, a modular end effector, a material handling device, and a sensor.

19. The method of claim 11, the operations further comprising:
evaluating the simulated construction process.

20. The method of claim 19, the operations further comprising:
based on a result of the operation of evaluating, iteratively performing at least one additional instance of the operations of receiving, generating, and simulating.
